(19) United States
(12) Patent Application Publication
(10) Pub. No.: US 2025/0118629 A1
(43) Pub. Date: Apr. 10, 2025

(54) COOLER AND COOLING STRUCTURE FOR SEMICONDUCTOR DEVICE

(71) Applicant: ROHM CO., LTD., Kyoto-shi (JP)

(72) Inventor: Tomohiro YASUNISHI, Kyoto-shi (JP)

(21) Appl. No.: 18/986,384

(22) Filed: Dec. 18, 2024

Related U.S. Application Data
(63) Continuation of application No. PCT/JP2023/022097, filed on Jun. 14, 2023.

(30) Foreign Application Priority Data
Jun. 29, 2022 (JP) 2022-104493

(51) Int. Cl. H01L 23/46; H01L 25/07

(52) U.S. Cl. CPC H01L 23/46; H01L 25/072

(57) ABSTRACT

A cooler includes: a housing that includes an opening, an internal space, and a bottom; and a partition wall that rises in a first direction from the bottom and that is accommodated in the internal space. The housing includes an inlet channel and an outlet channel that are connected to the internal space. The internal space includes a first reservoir and a second reservoir that are partitioned by the partition wall. The first reservoir is connected to the inlet channel. The second reservoir is connected to the outlet channel. The partition wall includes an overflow section that overlaps with the opening as viewed in the first direction and is farthest from the bottom. The overflow section is located between the bottom and the opening.

### TECHNICAL FIELD

The present disclosure relates to a cooler and also to a cooling structure that includes the cooler and a semiconductor device attached to the cooler, the cooling structure being for a semiconductor device.

### BACKGROUND ART

WO2017/094370 discloses an example of a cooler provided with a semiconductor device. The cooler includes a housing with a hollow interior, and a radiator. The housing has an opening that is in communication with the hollow interior. The radiator is attached to the housing to close the opening. A portion of the radiator is housed in the hollow interior. The semiconductor device is joined to a portion of the radiator located outside the hollow interior. When coolant flows into the hollow interior, the coolant comes into contact with radiator. In this way, the semiconductor device is cooled through the radiator.

In the cooler disclosed in WO2017/094370, the radiator interferes with the flow direction of the coolant. This reduces the energy in the flow of coolant, which may lead to insufficient distribution of coolant throughout the entire portion of the radiator that is housed in the hollow interior. This can be a factor that reduces the cooling efficiency of the cooler.

### BRIEF DESCRIPTION OF THE DRAWINGS

FIG. 1 is an exploded perspective view of a cooler according to a first embodiment of the present disclosure.

FIG. 2 is a plan view of the cooler shown in FIG. 1.

FIG. 3 is a bottom view of the cooler shown in FIG. 1.

FIG. 4 is a perspective view of a housing of the cooler shown in FIG. 1, with a bottom omitted.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a perspective view of a semiconductor device included in a cooling structure shown in FIG. 22.

FIG. 10 is a plan view of the semiconductor device shown in FIG. 9.

FIG. 11 is a plan view corresponding to FIG. 10, with a sealing resin shown as transparent.

FIG. 12 is a partially enlarged view of FIG. 11.

FIG. 13 is a plan view corresponding to FIG. 10, with a first conductive member shown as transparent, and the sealing resin and a second conductive member omitted.

FIG. 14 is a right-side view of the semiconductor device shown in FIG. 9.

FIG. 15 is a bottom view of the semiconductor device shown in FIG. 9.

FIG. 16 is a sectional view taken along line XVI-XVI in FIG. 11.

FIG. 17 is a sectional view taken along line XVII-XVII in FIG. 11.

FIG. 18 is a partially enlarged view showing a portion around a first element shown in FIG. 17.

FIG. 19 is a partially enlarged view showing a portion around a second element shown in FIG. 17.

FIG. 20 is a sectional view taken along line XX-XX in FIG. 11.

FIG. 21 is a sectional view taken along line XXI-XXI in FIG. 11.

FIG. 22 is a plan view of a cooling structure for a semiconductor device, according to the first embodiment of the present disclosure.

FIG. 23 is a sectional view taken along line XXIII-XXIII in FIG. 22.

FIG. 24 is an exploded perspective view of a cooler according to a second embodiment of the present disclosure.

FIG. 25 is a plan view of the cooler shown in FIG. 24.

FIG. 26 is a sectional view taken along line XXVI-XXVI in FIG. 25.

FIG. 27 is a sectional view taken along line XXVII-XXVII in FIG. 25.

FIG. 28 is a perspective view of a lid member of the cooler shown in FIG. 24.

FIG. 29 is a plan view of a cooling structure for a semiconductor device, according to the second embodiment of the present disclosure.

FIG. 30 is a sectional view taken along line XXX-XXX in FIG. 29.

FIG. 31 is a plan view of a cooler according to a third embodiment of the present disclosure, with a lid member shown as transparent.

FIG. 32 is a sectional view taken along line XXXII-XXXII in FIG. 31.

FIG. 33 is a sectional view taken along line XXXIII-XXXIII in FIG. 31.

FIG. 34 is a plan view of a cooler according to a fourth embodiment of the present disclosure.

FIG. 35 is a sectional view taken along line XXXV-XXXV in FIG. 34.

FIG. 36 is a sectional view taken along line XXXVI-XXXVI in FIG. 34.

FIG. 37 is a sectional view taken along line XXXVII-XXXVII in FIG. 34.

FIG. 38 is a plan view of a cooling structure for semiconductor devices, according to the third embodiment of the present disclosure.

### DETAILED DESCRIPTION OF EMBODIMENTS

Embodiments for carrying out the present disclosure are described with reference to the attached drawings.

### First Embodiment (Cooler)

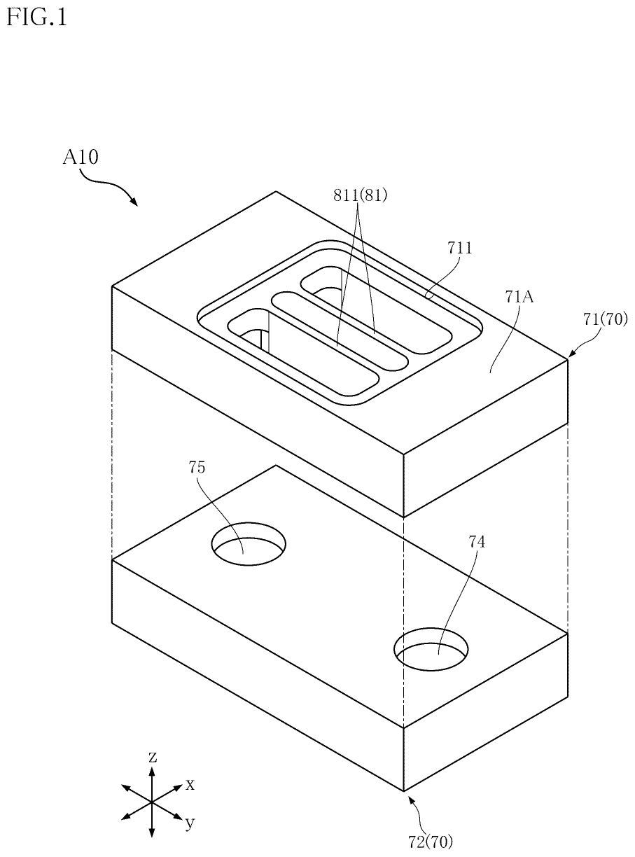

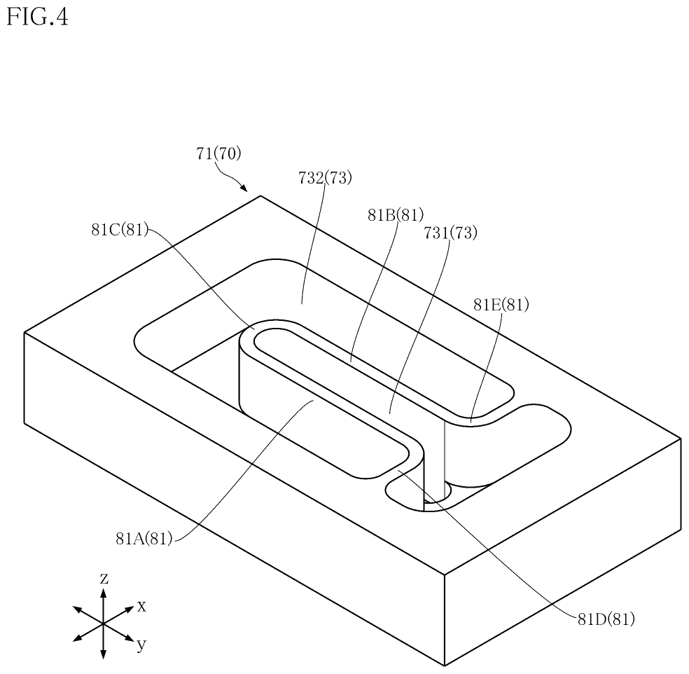

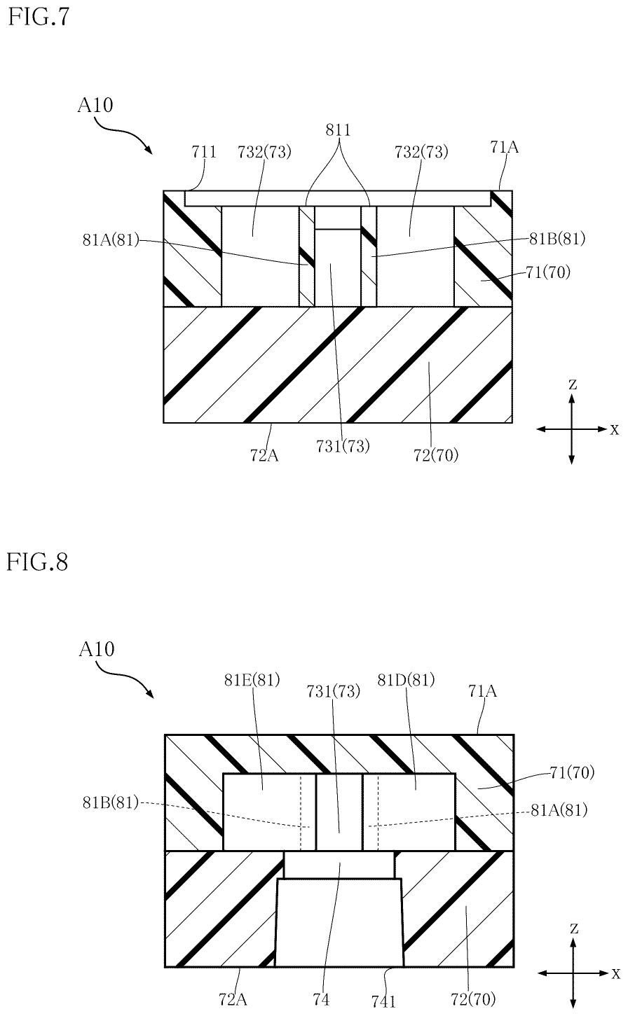

With reference to FIGS. 1 to 8, a cooler A10 according to a first embodiment of the present disclosure is described. The cooler A10 is used to cool a semiconductor device B included in a cooling structure C10, which will be described later. The cooler A10 includes a housing 70 and a partition wall 81. For the convenience of description, FIG. 4 omits a later-described bottom 72 of the housing 70.

In the description of the cooler A10, the direction normal to a later-described obverse surface 71A of the housing 70 is referred to as a “first direction z”. A direction orthogonal to the first direction z is referred to as a “second direction x”. The direction orthogonal to the first direction z and the second direction x is referred to as a “third direction y”. The first direction z, the second direction x, and the third direction y will be also used in the description of the semiconductor device B and the cooling structure C10 below.

As shown in FIG. 1, the housing 70 includes a body 71 and a bottom 72. The bottom 72 is attached to the body 71. In the cooler A10, the body 71 and the bottom 72 are each made of a material containing resin. Alternatively, the body 71 and the bottom 72 may each be made of a material containing metal. For the present disclosure, the material for each of the body 71 and the bottom may be freely selected.

As shown in FIGS. 1, 2, and 5 to 7, the body 71 has an obverse surface 71A and an opening 711. The obverse surface 71A faces a first side in the first direction z. The opening 711 is located on the first side in the first direction z. The opening 711 is connected to the obverse surface 71A and surrounded by the obverse surface 71A.

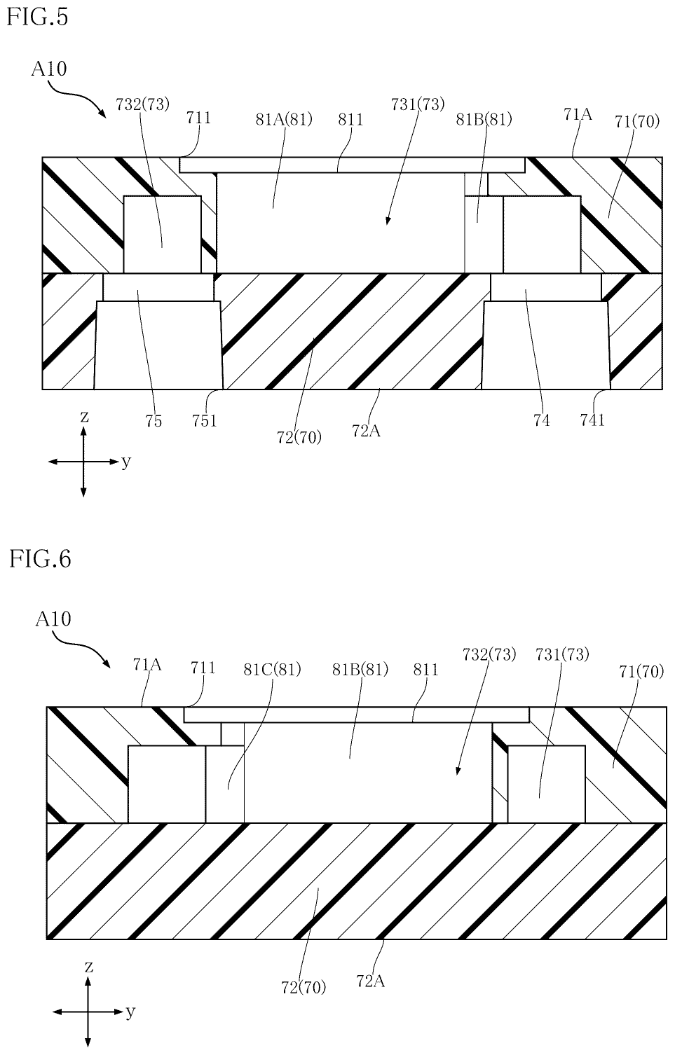

As shown in FIGS. 5 to 7, the bottom 72 is located opposite the opening 711 of the body 71 with respect to an internal space 73, which will be described later. The bottom 72 closes the body 71. The bottom 72 has a reverse surface 72A. The reverse surface 72A faces away from the obverse surface 71A of the body 71 in the first direction z.

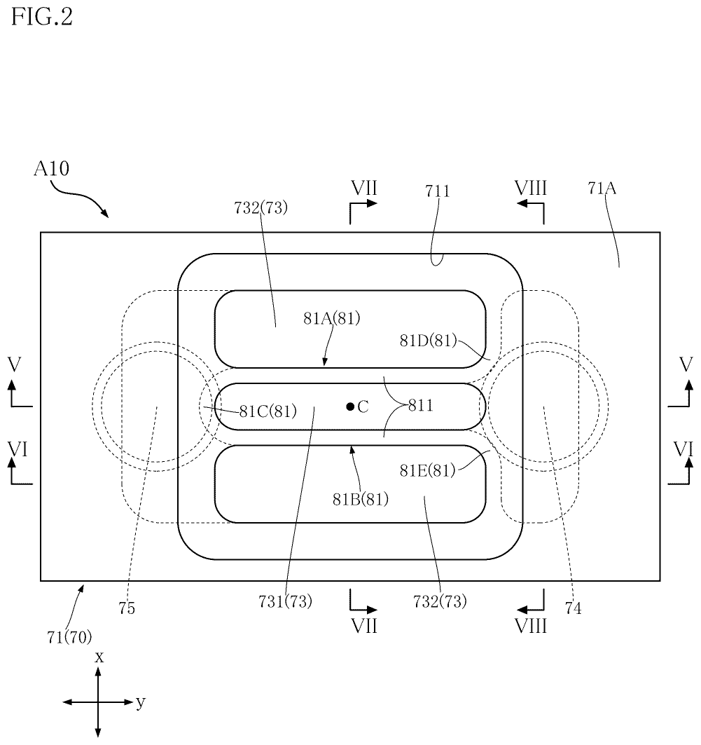

As shown in FIGS. 2 and 4 to 8, the housing 70 has the internal space 73. The internal space 73 is connected to the opening 711 of the body 71. The internal space 73 is located inside the body 71. Each of the body 71 and the bottom 72 defines a part of the internal space 73.

As shown in FIGS. 1, 3, and 5, the bottom 72 is provided with an inlet channel 74 and an outlet channel 75. Each of the inlet channel 74 and the outlet channel 75 is connected to the internal space 73 and penetrates the bottom 72 in the first direction z. The inlet channel 74 and the outlet channel 75 are spaced apart from each other in the third direction y. The inlet channel 74 has an inlet 741. The inlet 741 is connected to the reverse surface 72A. The outlet channel 75 has an outlet 751. The outlet 751 is connected to the reverse surface 72A. A connecting member (not shown) is attached to each of the inlet 741 and the outlet 751 for receiving coolant from the outside or discharging coolant to the outside.

As shown in FIGS. 2 and 4 to 8, the partition wall 81 is accommodated within the internal space 73 of the housing 70. The partition wall 81 rises in the first direction z from the bottom 72. For the cooler A10, the partition wall 81 is made of a material containing resin. The partition wall 81 is an integral portion of the body 71. In another example, the partition wall 81 may be attached to the body 71. The partition wall 81 is exposed through the opening 711 of the body 71.

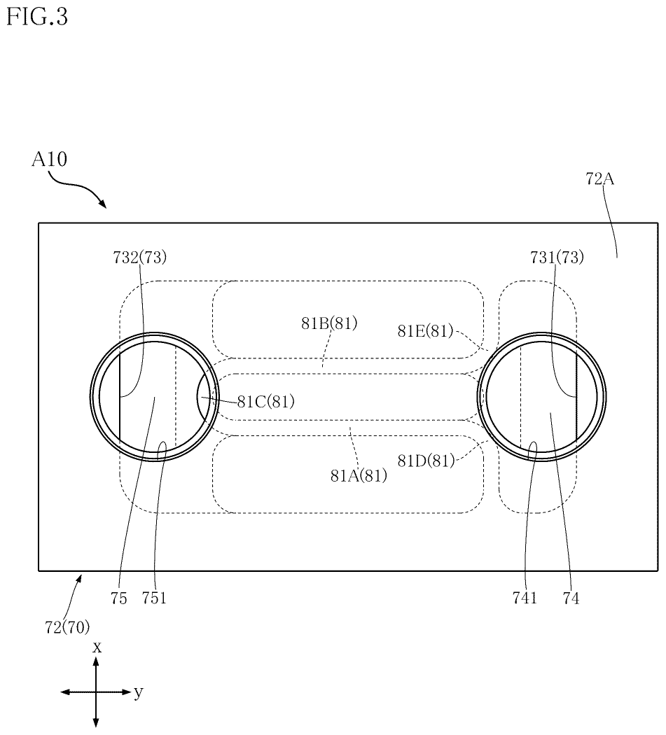

As shown in FIGS. 2 and 4, the internal space 73 includes a first reservoir 731 and a second reservoir 732 that are partitioned by the partition wall 81. As shown in FIGS. 3 and 5, the first reservoir 731 is connected to the inlet channel 74. The second reservoir 732 is connected to the outlet channel 75.

As shown in FIGS. 1, 2, and 5 to 7, the partition wall 81 has an overflow section 811. As viewed in the first direction z, the overflow section 811 overlaps with the opening 711 of the body 71. The overflow section 811 is a portion farthest from the bottom 72. The overflow section 811 is located between the bottom 72 and the opening 711 in the first direction z. In the cooler A10, the overflow section 811 is spaced apart from the opening 711 in the first direction z.

The cooler A10 is fed with coolant from the outside through the inlet 741. Then, the coolant flows from the inlet channel 74 into the first reservoir 731. As more coolant is fed, the liquid level of the coolant in the first reservoir 731 rises. Eventually, the liquid level of the coolant reaches a point farther away from the bottom 72, exceeding the overflow section 811 of the partition wall 81. The coolant thus flows over the overflow section 811 and down into the second reservoir 732. The coolant in the second reservoir 732 then flows through the outlet channel 75 and is discharged to the outside from the outlet 751. Thus, the flow of coolant in the internal space 73 includes the component in the first direction z. The coolant discharged to the outside from the outlet 751 is cooled again and introduced into the cooler A10 through the inlet 741. In this way, the coolant is circulated between the cooler A10 and the outside.

As shown in FIGS. 2 to 4, the partition wall 81 includes a first partition wall 81A and a second partition wall 81B. As viewed in the first direction z, the first partition wall 81A and the second partition wall 81B overlap with the opening 711 of the body 71. The first partition wall 81A and the second partition wall 81B are spaced apart from each other in the second direction x. The first partition wall 81A and the second partition wall 81B extend in the third direction y. Each of the first partition wall 81A and the second partition wall 81B includes an overflow section 811.

As shown in FIGS. 2 and 4, in the cooler A10, the first reservoir 731 is located between the first partition wall 81A and the second partition wall 81B. As viewed in the first direction z, the first reservoir 731 overlaps with the center C of the opening 711 of the body 71. Alternatively, the second reservoir 732 may be located between the first partition wall 81A and the second partition wall 81B, provided that the positions of the inlet channel 74 and the outlet channel 75 are exchanged. That is, in the cooler A10, either the first reservoir 731 or the second reservoir 732 is located between the first partition wall 81A and the second partition wall 81B.

As shown in FIGS. 2 to 4, the partition wall 81 includes a third partition wall 81C, a fourth partition wall 81D, and a fifth partition wall 81E. The third partition wall 81C is located opposite the inlet channel 74 in the third direction y with respect to the first partition wall 81A and the second partition wall 81B. The third partition wall 81C connects the first partition wall 81A and the second partition wall 81B. The fourth partition wall 81D and the fifth partition wall 81E are located opposite the third partition wall 81C with respect to the first partition wall 81A and the second partition wall 81B. The fourth partition wall 81D connects the first partition wall 81A and the body 71. The fifth partition wall 81E connects the second partition wall 81B and the body 71. Each of the third, fourth, and fifth partition walls 81C, 81D, and 81E includes a first curved surface facing the first reservoir 731 and a second curved surface facing the second reservoir 732.

### Semiconductor Device B

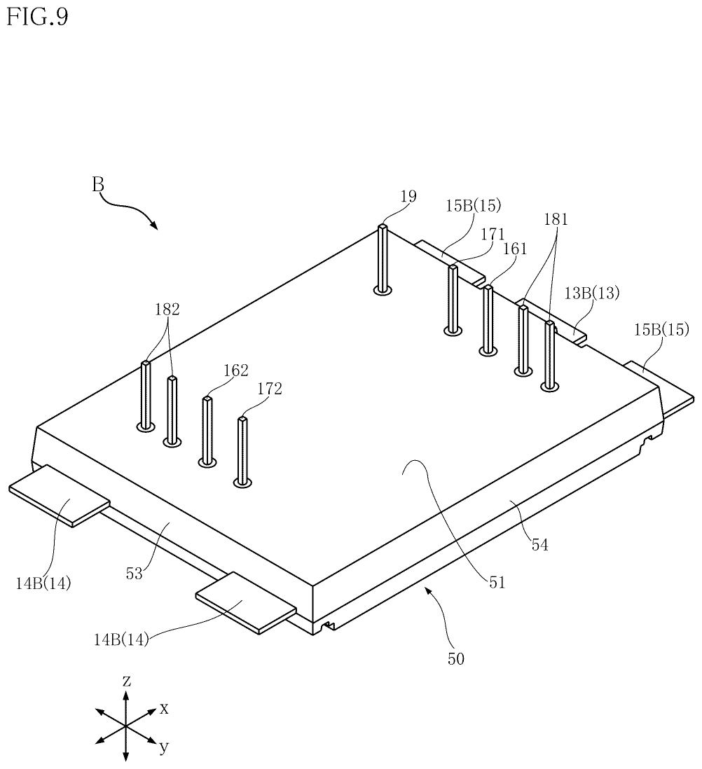

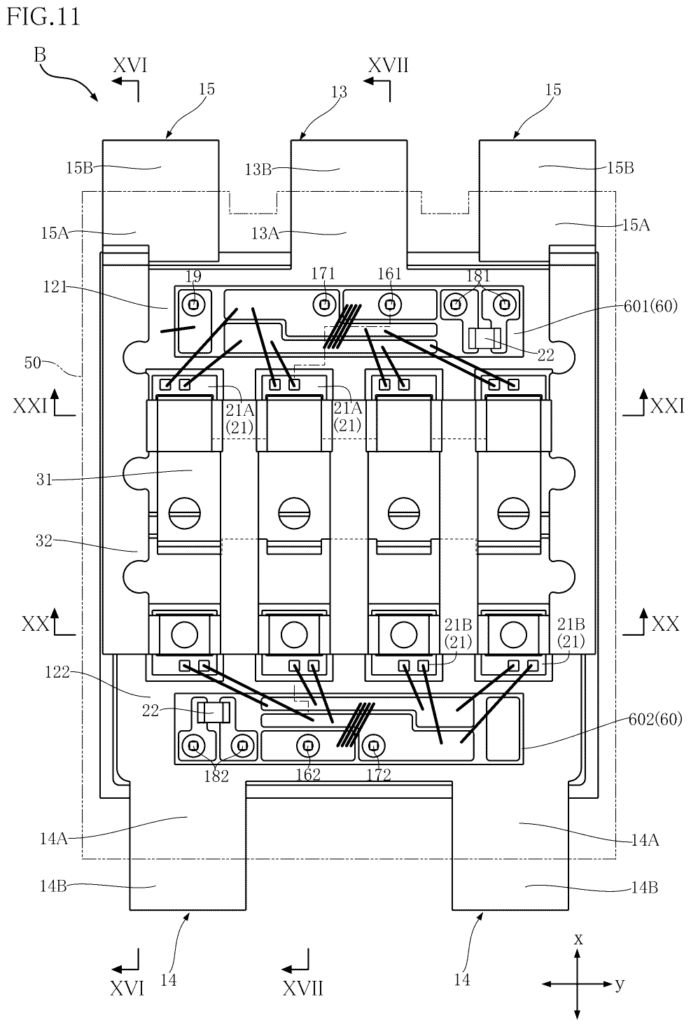

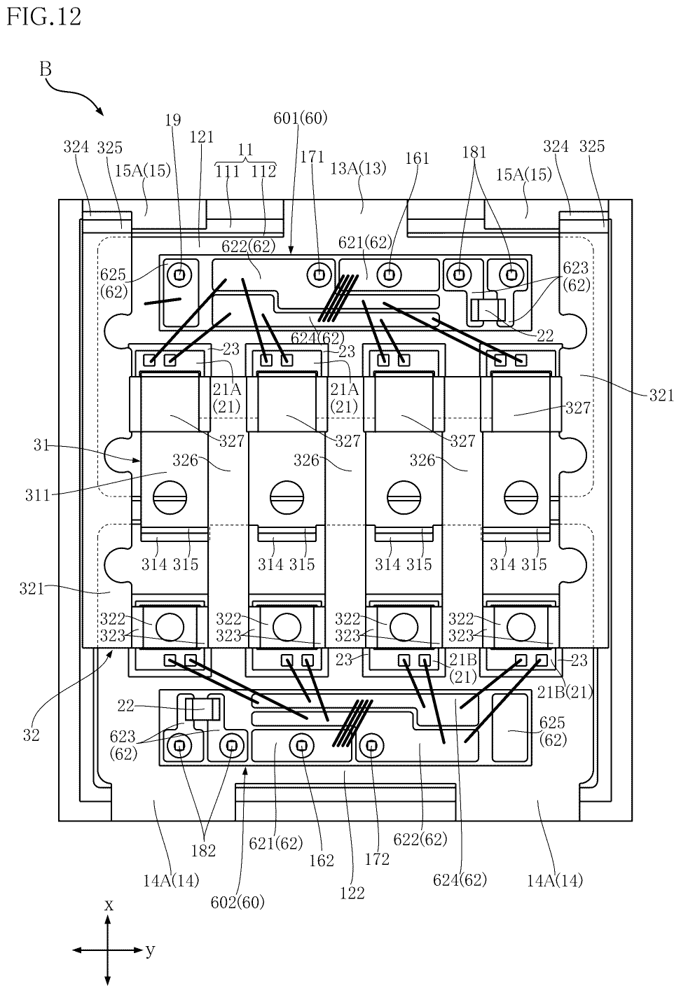

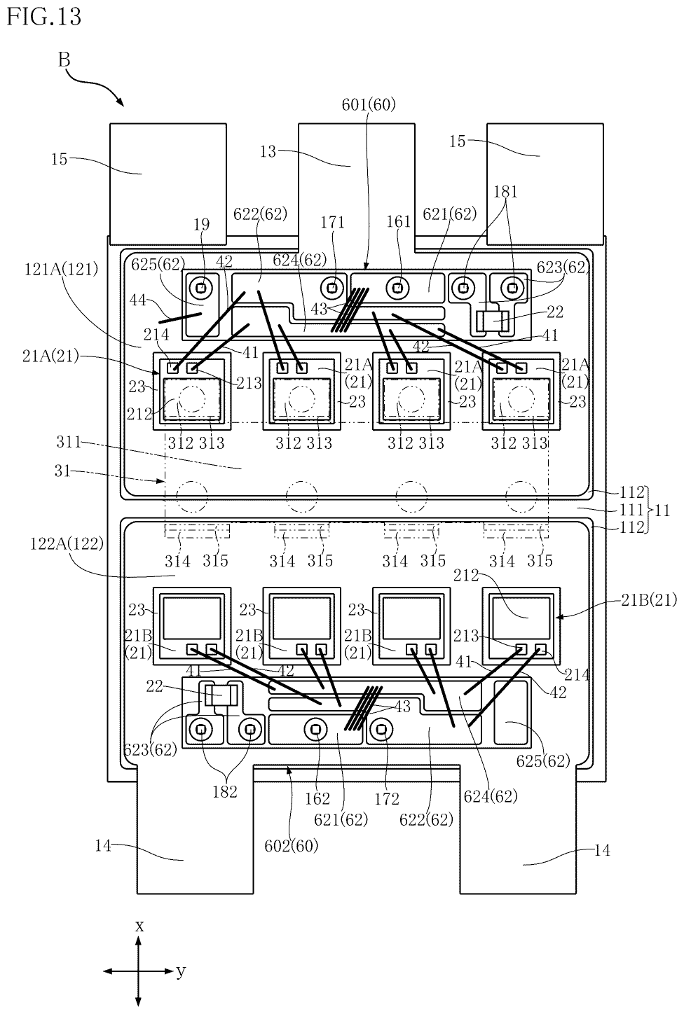

With reference to FIGS. 9 to 21, the following describes a semiconductor device B that is included in a cooling structure C10, which will be described later. The semiconductor device B includes a substrate 11, a first conductive layer 121, a second conductive layer 122, a first input terminal 13, an output terminal 14, a second input terminal 15, a first signal terminal 161, a second signal terminal 162, a plurality of semiconductor elements 21, a first conductive member 31, a second conductive member 32, and a sealing resin 50. The semiconductor device B also includes a third signal terminal 171, a fourth signal terminal 172, a pair of fifth signal terminals 181, a pair of sixth signal terminals 182, a seventh signal terminal 19, a pair of thermistors 22, and a pair of control wirings 60. For the convenience of description, FIGS. 11 and 12 show the sealing resin 50 as transparent. In FIG. 11, the outline of the sealing resin 50 is indicated by an imaginary line (two-dot-dash line). For the convenience of description, FIG. 13 shows the first conductive member 31 as transparent, and omits the second conductive member 32 and the sealing resin 50. In the FIG. 13, the outline of the first conductive member 31 is indicated by an imaginary line. In addition, FIG. 11 shows the XVII-XVII line as a dot-dash line.

The semiconductor device B converts DC power supply voltage that is applied to the first input terminal 13 and the second input terminal 15 into AC power using the semiconductor elements 21. The resulting AC power is output from the output terminal 14 to a power supply target, such as a motor.

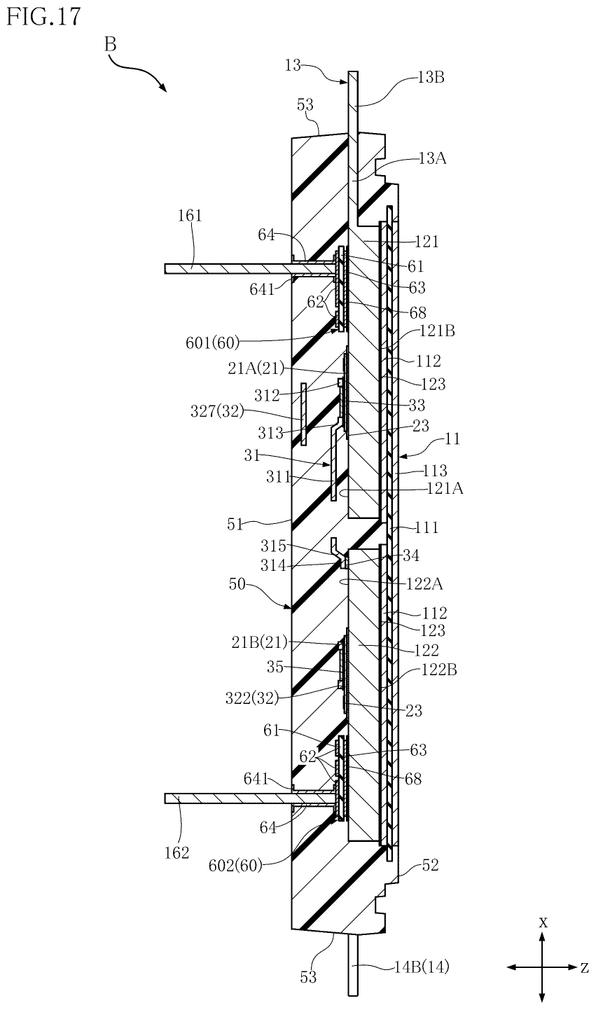

As shown in FIGS. 17 to 19, the substrate 11 is located opposite the plurality of semiconductor elements 21 in the first direction z across the first conductive layer 121 and the second conductive layer 122. The substrate 11 supports the first conductive layer 121 and the second conductive layer 122. The substrate 11 of the semiconductor device B is formed from a direct bonded copper (DBC). As shown in FIGS. 17 to 19, the substrate 11 includes an insulating layer 111, an intermediate layer 112, and a heat dissipating layer 113. The substrate is covered with the sealing resin 50, except for a portion of the heat dissipating layer 113.

As shown in FIGS. 17 to 19, the insulating layer 111 has a portion interposed between the intermediate layer 112 and the heat dissipating layer 113 in the first direction z. The insulating layer 111 is made of a material with relatively high thermal conductivity. For example, the insulating layer 111 is made of a ceramic material containing aluminum nitride (AlN). Alternatively, the insulating layer 111 may be made of an insulating resin sheet rather than a ceramic material. The insulating layer 111 is thinner than the first conductive layer 121 and the second conductive layer 122.

As shown in FIGS. 17 to 19, the intermediate layer 112 is located between the insulating layer 111 and each of the first conductive layer 121 and the second conductive layer 122 in the first direction z. The intermediate layer 112 includes a pair of regions that are spaced apart from each other in the second direction x. The composition of the intermediate layer 112 includes copper (Cu). As shown in FIG. 13, the intermediate layer 112 is surrounded by the peripheral edge of the insulating layer 111 as viewed in the first direction z.

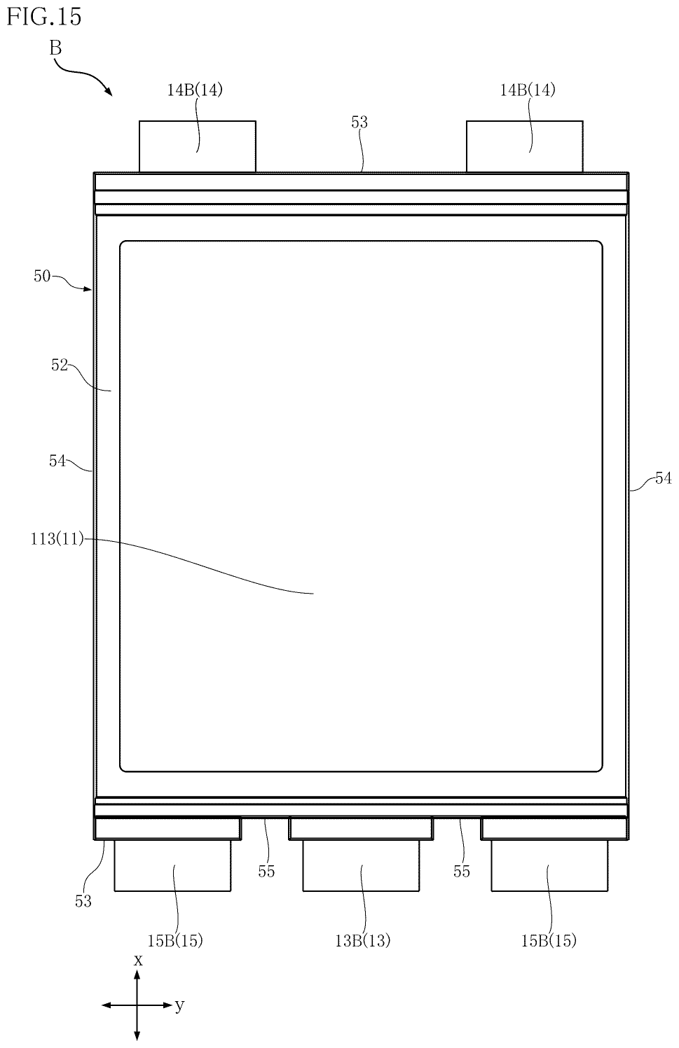

As shown in FIGS. 17 to 19, the heat dissipating layer 113 is located opposite the intermediate layer 112 in the first direction z across the insulating layer 111. As shown in FIG. 15, the heat dissipating layer 113 is exposed from the sealing resin 50. The composition of the heat dissipating layer 113 includes copper. The heat dissipating layer 113 is thicker than the insulating layer 111. As viewed in the first direction z, the heat dissipating layer 113 is surrounded by the peripheral edge of the insulating layer 111.

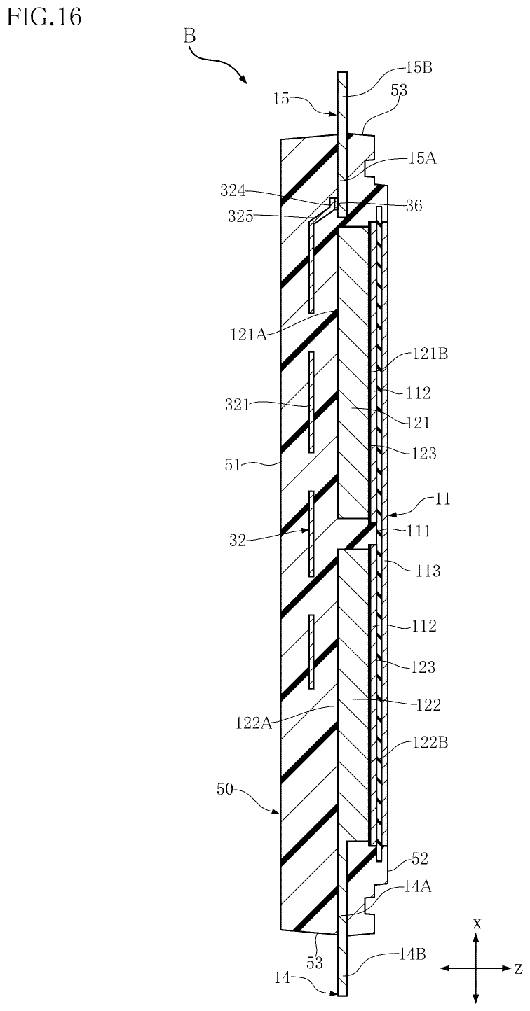

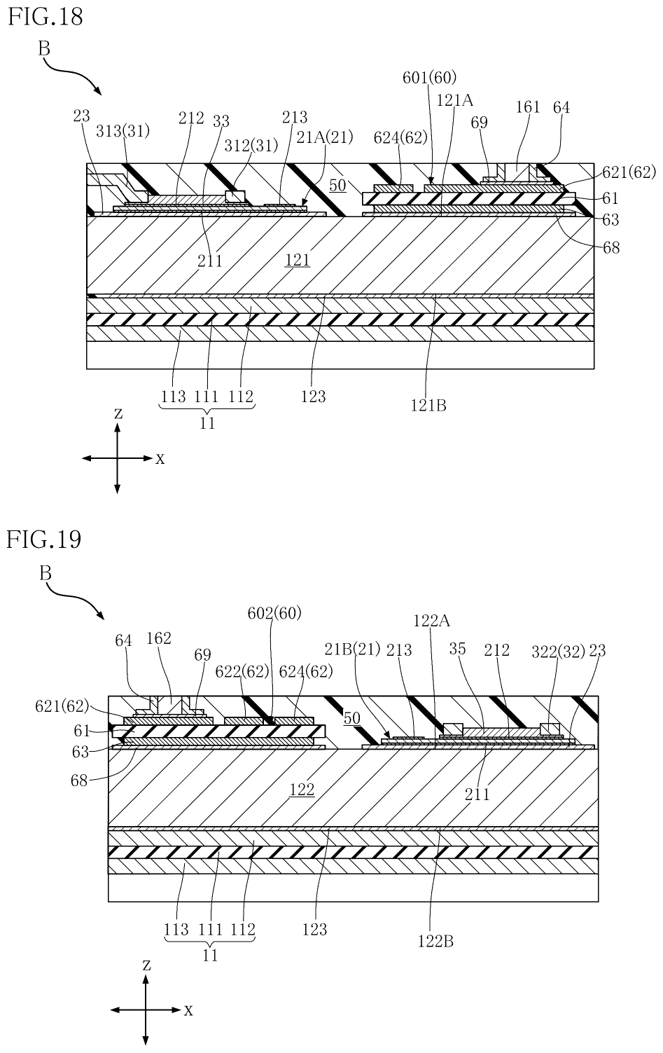

As shown in FIGS. 17 to 19, the first conductive layer 121 and the second conductive layer 122 are bonded to the substrate 11. The composition of the first conductive layer 121 and the second conductive layer 122 includes copper. The first conductive layer 121 and the second conductive layer 122 are spaced apart from each other in the second direction x. As shown in FIGS. 16 and 17, the first conductive layer 121 has a first obverse surface 121A and a first reverse surface 121B facing away from each other in the first direction z. The first obverse surface 121A faces the plurality of semiconductor elements 21. As shown in FIG. 18, the first reverse surface 121B is bonded to one of the pair of regions of the intermediate layer 112 via a first adhesive layer 123. The first adhesive layer 123 is a brazing filler material whose composition includes silver (Ag), for example. As shown in FIGS. 16 and 17, the second conductive layer 122 has a second obverse surface 122A and a second reverse surface 122B facing away from each other in the first direction z. The second obverse surface 122A faces the same side as the first obverse surface 121A in the first direction z. As shown in FIG. 19, the second reverse surface 122B is bonded to the other of the pair of regions of the intermediate layer 112 via the first adhesive layer 123.

As shown in FIGS. 13 and 17, each semiconductor element 21 is mounted either on the first conductive layer 121 or on the second conductive layer 122. For example, the semiconductor elements 21 are metal-oxide-semiconductor field-effect transistors (MOSFETS). Alternatively, the semiconductor elements 21 may be switching elements, such as insulated gate bipolar transistors (IGBTs), or diodes. The semiconductor device B is described using an example in which the semiconductor elements 21 are n-channel vertical MOSFETs. Each semiconductor element 21 includes a compound semiconductor substrate. The composition of the compound semiconductor substrate includes a silicon carbide (Sic).

As shown in FIG. 13, the semiconductor elements 21 of the semiconductor device B include a plurality of first elements 21A and a plurality of second elements 21B. The second elements 21B are identical in configuration to the first elements 21A. The first elements 21A are mounted on the first obverse surface 121A of the first conductive layer 121. The first elements 21A are arranged along the third direction y. The second elements 21B are mounted on the second obverse surface 122A of the second conductive layer 122. The second elements 21B are arranged along the third direction y.

As shown in FIGS. 13, 18, and 19, each semiconductor element 21 includes a first electrode 211, a second electrode 212, a third electrode 213, and a fourth electrode 214.

As shown in FIGS. 18 and 19, the first electrode 211 of each semiconductor element 21 faces either the first conductive layer 121 or the second conductive layer 122. The first electrode 211 passes the electric current corresponding to the power before conversion by the semiconductor element 21. That is, the first electrode 211 is the drain electrode of the semiconductor element 21.

As shown in FIGS. 18 and 19, the second electrode 212 of each semiconductor element 21 is located opposite the first electrode 211 in the first direction z. The second electrode 212 passes the electric current corresponding to the power having been converted by the semiconductor element 21. That is, the second electrode 212 is the source electrode of the semiconductor element 21.

As shown in FIGS. 18 and 19, the third electrode 213 of each semiconductor element 21 is located on the same side as the second electrode 212 in the first direction z. The third electrode 213 receives a gate voltage applied to drive the semiconductor element 21. That is, the third electrode 213 is the gate electrode of the semiconductor element 21. As shown in FIG. 13, the third electrode 213 has a smaller area than the second electrode 212 as viewed in the first direction Z.

As shown in FIG. 13, the fourth electrode 214 is located on the same side as the second electrode 212 in the first direction z and next to the third electrode 213 in the third direction y. The fourth electrode 214 is at the same potential as the second electrode 212.

As shown in FIGS. 18 and 19, a conductive bonding layer 23 is provided between each of the first conductive layer 121 and the second conductive layer 122 and the first electrode 211 of each semiconductor element 21. The conductive bonding layer 23 may be solder, for example. Alternatively, the conductive bonding layer 23 may contain sintered metal particles. The first electrode 211 of each first element 21A is electrically bonded to the first obverse surface 121A of the first conductive layer 121 via the conductive bonding layer 23. This electrically connects the first electrode 211 of each first element 21A to the first conductive layer 121. The first electrode 211 of each second element 21B is electrically bonded to the second obverse surface 122A of the second conductive layer 122 via the conductive bonding layer 23. This electrically connects the first electrode 211 of each second element 21B to the second conductive layer 122.

As shown in FIGS. 11 and 17, the first input terminal 13 is located opposite the second conductive layer 122 in the second direction x across the first conductive layer 121 and is connected to the first conductive layer 121. Thus, the first input terminal 13 is electrically connected to the first electrodes 211 of the first elements 21A via the first conductive layer 121. The first input terminal 13 is a P terminal (positive terminal) to which DC power supply voltage to be converted is applied. The first input terminal 13 extends in the second direction x from the first conductive layer 121. The first input terminal 13 includes a covered portion 13A and an exposed portion 13B. As shown in FIG. 17, the covered portion 13A is connected to the first conductive layer 121 and is covered with the sealing resin 50. The covered portion 13A is flush with the first obverse surface 121A of the first conductive layer 121. The exposed portion 13B extends in the second direction x from the covered portion 13A and is exposed from the sealing resin 50.

As shown in FIGS. 11 and 16, the output terminal 14 is located opposite the first conductive layer 121 in the second direction x across the second conductive layer 122 and is connected to the second conductive layer 122. Thus, the output terminal 14 is electrically connected to the first electrodes 211 of the second elements 21B via the second conductive layer 122. The output terminal 14 outputs the AC power converted by the semiconductor elements 21. In the semiconductor device B, the output terminal 14 includes a pair of regions spaced apart from each other in the third direction y. Alternatively, the output terminal 14 may be composed of a single structure not including a pair of separate regions. The output terminal 14 includes a covered portion 14A and an exposed portion 14B. As shown in FIG. 16, the covered portion 14A is connected to the second conductive layer 122 and is covered with the sealing resin 50. The covered portion 14A is flush with the second obverse surface 122A of the second conductive layer 122. The exposed portion 14B extends in the second direction x from the covered portion 14A and is exposed from the sealing resin 50.

As shown in FIGS. 11 and 16, the second input terminal 15 is located on the same side as the first input terminal 13 in the second direction x with respect to the first conductive layer 121 and the second conductive layer 122, and is spaced apart from the first conductive layer 121 and the second conductive layer 122. The second input terminal 15 is electrically connected to the second electrodes 212 of the second elements 21B. The second input terminal 15 is an N terminal (negative terminal) to which DC power supply voltage to be converted is applied. The second input terminal 15 includes a pair of regions spaced apart from each other in the third direction y. The first input terminal 13 is located between these regions in the third direction y. The second input terminal 15 includes a covered portion 15A and an exposed portion 15B. As shown in FIG. 16, the covered portion 15A is spaced apart from first conductive layer 121 and is covered with the sealing resin 50. The exposed portion 15B extends in the second direction x from the covered portion 15A and is exposed from the sealing resin 50.

The pair of control wirings 60 form portions of the conduction paths connecting the semiconductor elements 21 and the signal terminals, namely the first signal terminal 161, the second signal terminal 162, the third signal terminal 171, the fourth signal terminal 172, the fifth signal terminals 181, and the sixth signal terminals 182. As shown in FIGS. 11 to 13, the pair of control wirings 60 include a first wiring 601 and a second wiring 602. In the second direction x, the first wiring 601 is located between the plurality of first elements 21A and the first and second input terminals 13 and 15. The first wiring 601 is bonded to the first obverse surface 121A of the first conductive layer 121. The first wiring 601 also forms a portion of a conduction path between the seventh signal terminal 19 and the first conductive layer 121. In the second direction x, the second wiring 602 is located between the plurality of second elements 21B and the output terminal 14. The second wiring 602 is bonded to the second obverse surface 122A of the second conductive layer 122. As shown in FIGS. 18 and 19, each control wiring 60 includes an insulating layer 61, a plurality of wiring layers 62, a metal layer 63, and a plurality of sleeves 64. The control wirings 60 are covered with the sealing resin 50, except for a portion of each sleeve 64.

As shown in FIGS. 18 and 19, the insulating layer 61 includes portions interposed between the respective wiring layers 62 and the metal layer 63 in the first direction z. The insulating layer 61 is made of a ceramic material, for example. Alternatively, the insulating layer 61 may be made of an insulating resin sheet rather than a ceramic material.

As shown in FIGS. 18 and 19, the plurality of wiring layers 62 are located on the first side of the insulating layer 61 in the first direction z. The composition of the wiring layers 62 includes copper. As shown in FIG. 13, the plurality of wiring layers 62 include a first wiring layer 621, a second wiring layer 622, a pair of third wiring layers 623, a fourth wiring layer 624, and a fifth wiring layer 625. The third wiring layers 623 are next to each other in the third direction y.

As shown in FIGS. 18 and 19, the metal layer 63 is located opposite the plurality of wiring layers 62 in the first direction z across the insulating layer 61. The composition of the metal layer 63 includes copper. The metal layer 63 of the first wiring 601 is bonded to the first obverse surface 121A of the first conductive layer 121 by a second adhesive layer 68. The metal layer 63 of the second wiring 602 is bonded to the second obverse surface 122A of the second conductive layer 122 by a second adhesive layer 68. The material of the second adhesive layer 68 may be conductive or non-conductive. The second adhesive layer 68 may be solder, for example.

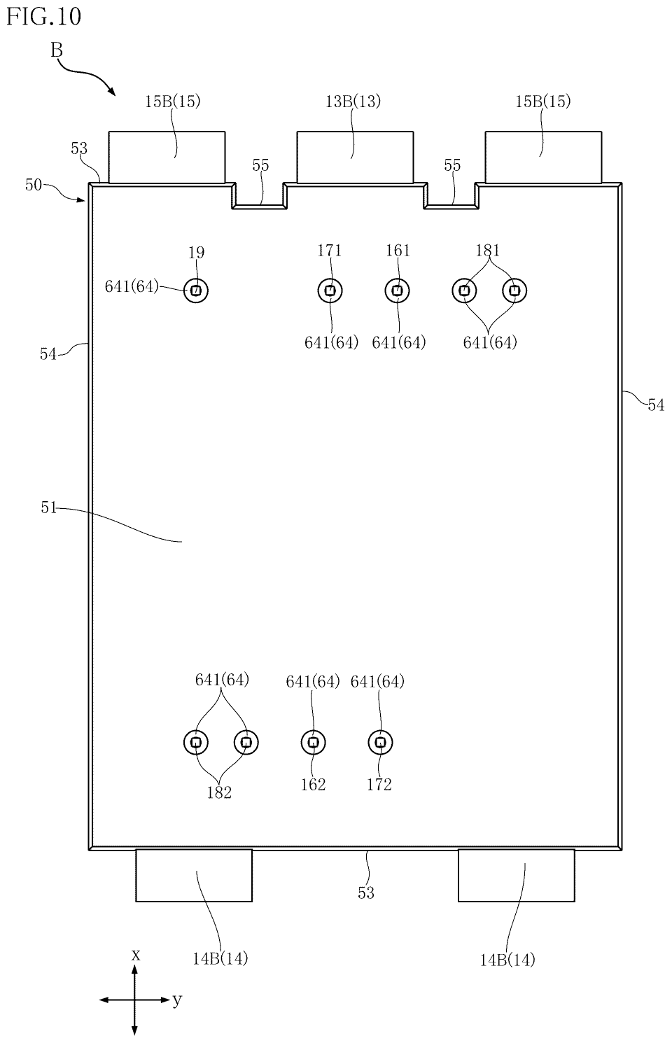

As shown in FIGS. 18 and 19, each sleeve 64 is bonded to one of the wiring layers 62 by a third adhesive layer 69. The sleeves 64 are made of a conductive material, such as metal. Each sleeve 64 is a tubular structure extending in the first direction z. Each sleeve 64 is electrically bonded at one end to one of the wiring layers 62. Each sleeve 64 has an end surface 641 at the other end that is exposed above the top surface 51 of the sealing resin 50 as shown in FIGS. 10 and 17. The third adhesive layer 69 is conductive. The third adhesive layer 69 may be solder, for example.

As shown in FIG. 12, one of the pair of thermistors 22 is electrically bonded to both of the third wiring layers 623 of the first wiring 601. The other thermistor 22 is electrically bonded to both of the third wiring layers 623 of the second wiring 602 as shown in FIG. 12. The thermistors 22 are negative temperature coefficient (NTC) thermistors, for example. An NTC thermistor has a resistance that gradually decreases as the temperature increases. The sensors for the thermistors 22 are used as temperature semiconductor device B.

As shown in FIG. 9, the first to seventh signal terminals 161, 162, 171, 172, 181, 182, and 19 are made of metal pins extending in the first direction z. These signal terminals protrude from the top surface 51, which will be described later, of the sealing resin 50. In addition, these signal terminals are press-fitted into the respective sleeves 64 of That is, each signal terminal is the control wirings 60. supported by one of the sleeves 64 and electrically connected to one of the wiring layers 62.

As shown in FIGS. 13 and 18, the first signal terminal 161 is fitted into the sleeve 64 that is electrically bonded to the first wiring layer 621 of the first wiring 601, among the plurality of sleeves 64 of the control wirings 60. That is, the first signal terminal 161 is supported by the sleeve 64 and electrically connected to the first wiring layer 621 of the first wiring 601. Thus, the first signal terminal 161 is electrically connected to the third electrodes 213 of the first elements 21A. The gate voltage for driving the first elements 21A is applied to the first signal terminal 161.

As shown in FIGS. 13 and 19, the second signal terminal 162 is fitted into the sleeve 64 that is electrically bonded to the first wiring layer 621 of the second wiring 602, among the plurality of sleeves 64 of the control wirings 60. That is, the second signal terminal 162 is supported by the sleeve 64 and electrically connected to the first wiring layer 621 of the second wiring 602. Thus, the second signal terminal 162 is electrically connected to the third electrodes 213 of the second elements 21B. The gate voltage for driving the second elements 21B is applied to the second signal terminal 162.

As shown in FIG. 10, the third signal terminal 171 is located next to the first signal terminal 161 in the third direction y. As shown in FIG. 13, the third signal terminal 171 is fitted into the sleeve 64 that is bonded to the second wiring layer 622 of the first wiring 601, among the plurality of sleeves 64 of the control wirings 60. That is, the third signal terminal 171 is supported by the sleeve 64 and electrically connected to the second wiring layer 622 of the first wiring 601. Thus, the third signal terminal 171 is electrically connected to the fourth electrodes 214 of the first elements 21A. The third signal terminal 171 receives a voltage corresponding to the maximum current flowing through the fourth electrodes 214 of the first elements 21A.

As shown in FIG. 10, the fourth signal terminal 172 is located next to the second signal terminal 162 in the third direction y. As shown in FIG. 13, the fourth signal terminal 172 is fitted into the sleeve 64 that is bonded to the second wiring layer 622 of the second wiring 602, among the plurality of sleeves 64 of the control wirings 60. That is, the fourth signal terminal 172 is supported by the sleeve 64 and electrically connected to the second wiring layer 622 of the second wiring 602. Thus, the fourth signal terminal 172 is electrically connected to the fourth electrodes 214 of the second elements 21B. The fourth signal terminal 172 receives a voltage corresponding to the maximum current flowing through the fourth electrodes 214 of the second elements 21B.

As shown in FIG. 10, the pair of fifth signal terminals 181 are located opposite the third signal terminal 171 in the third direction y across the first signal terminal 161. The fifth signal terminals 181 are next to each other in the third direction y. As shown in FIG. 13, each fifth signal terminal 181 is fitted into the sleeve 64 that is bonded to one of the third wiring layers 623 of the first wiring 601, among the plurality of sleeves 64 of the control wirings 60. That is, each fifth signal terminal 181 is supported by the sleeve 64 and electrically connected to the corresponding one of third wiring layers 623 of the first wiring 601. Thus, each fifth signal terminal 181 is electrically connected to the thermistor 22 that is electrically bonded to the pair of third wiring layers 623 of the first wiring 601, out of the two thermistors 22.

As shown in FIG. 10, the pair of sixth signal terminals 182 are located opposite the fourth signal terminal 172 in the third direction y across the second signal terminal 162. The sixth signal terminal 182 are next to each other in the third direction y. As shown in FIG. 13, each sixth signal terminal 182 is fitted into the sleeve 64 that is bonded to one of the third wiring layers 623 of the second wiring 602, among the plurality of sleeves 64 of the control wirings 60. That is, each sixth signal terminal 182 is supported by the sleeve 64 and electrically connected to the corresponding one of third wiring layers 623 of the second wiring 602. Thus, each sixth signal terminal 182 is electrically connected to the thermistor 22 that is electrically bonded to the pair of third wiring layers 623 of the second wiring 602, out of the two thermistors 22.

As shown in FIG. 10, the seventh signal terminal 19 is located opposite the first signal terminal 161 in the third direction y across third signal terminal 171. As shown in FIG. 13, the seventh signal terminal 19 is fitted into the sleeve 64 that is bonded to the fifth wiring layer 625 of the first wiring 601, among the plurality of sleeves 64 of the control wirings 60. That is, the seventh signal terminal 19 is supported by the sleeve 64 and electrically connected to the fifth wiring layer 625 of the first wiring 601. Thus, the seventh signal terminal 19 is electrically connected to the first conductive layer 121. The seventh signal terminal 19 receives a voltage corresponding to the DC power inputted to the first input terminal 13 and the second input terminal 15.

As shown in FIG. 13, a plurality of first wires 41 include those electrically bonded to both the third electrodes 213 of the respective first elements 21A and the fourth wiring layer 624 of the first wiring 601. As shown in FIG. 13, a plurality of third wires 43 include those electrically bonded to both the fourth wiring layer 624 of the first wiring 601 and the first wiring layer 621 of the first wiring 601. Thus, the first signal terminal 161 is electrically connected to the third electrodes 213 of the first elements 21A. The composition of the first wires 41 and the third wires 43 includes gold (Au). Alternatively, the composition of the first wires 41 and the third wires 43 may include copper or aluminum.

As shown in FIG. 13, the plurality of first wires 41 additionally include those electrically bonded to both the third electrodes 213 of the respective second elements 21B and the fourth wiring layer 624 of the second wiring 602. As shown in FIG. 13, the plurality of third wires 43 additionally include those electrically bonded to both to the fourth wiring layer 624 of the second wiring 602 and the first wiring layer 621 of the second wiring 602. Thus, the second signal terminal 162 is electrically connected to the third electrodes 213 of the second elements 21B.

As shown in FIG. 13, a plurality of second wires 42 include those electrically bonded to both the fourth electrodes 214 of the respective first elements 21A and the second wiring layer 622 of the first wiring 601. Thus, the third signal terminal 171 is electrically connected to the fourth electrodes 214 of the first elements 21A. As shown in FIG. 13, the plurality of second wires 42 additionally include those electrically bonded to both the fourth electrodes 214 of the respective second elements 21B and the second wiring layer 622 of the second wiring 602. Thus, the fourth signal terminal 172 is electrically connected to the fourth electrodes 214 of the second elements 21B. The composition of the second wires 42 includes gold. Alternatively, the composition of the second wires 42 may include copper or aluminum.

As shown in FIG. 13, a fourth wire 44 is electrically bonded to the fifth wiring layer 625 of the first wiring 601 and the first obverse surface 121A of the first conductive layer 121. Thus, the seventh signal terminal 19 is electrically connected to the first conductive layer 121. The composition of the fourth wire 44 includes gold. Alternatively, the composition of the fourth wire 44 may include copper or aluminum.

As shown in FIGS. 13 and 18, the first conductive member 31 is electrically bonded to the second electrodes 212 of the respective first elements 21A and the second obverse surface 122A of the second conductive layer 122. This electrically connects the second electrodes 212 of the respective first elements 21A to the second conductive layer 122. The composition of the first conductive member 31 includes copper. The first conductive member 31 is a metal clip. As shown in FIG. 13, the first conductive member 31 includes a body 311, a plurality of first bonding portions 312, a plurality of first connecting portions 313, a second bonding portion 314, and a second connecting portion 315.

The body 311 is the major part of the first conductive member 31. As shown in FIG. 13, the body 311 extends in the third direction y. As shown in FIG. 17, the body 311 extends across the gap between the first conductive layer 121 and the second conductive layer 122.

As shown in FIG. 18, the first bonding portions 312 are bonded to the second electrodes 212 of the respective first elements 21A. Each first bonding portion 312 faces the second electrode 212 of the corresponding first element 21A.

As shown in FIG. 13, the first connecting portions 313 connect the body 311 and the first bonding portions 312. The first connecting portions 313 are spaced apart from each other in the third direction y. As shown in FIG. 17, each first connecting portion 313 as viewed in the third direction y is inclined away from the first obverse surface 121A of the first conductive layer 121 as it approaches the body 311 from the first bonding portion 312.

As shown in FIGS. 13 and 17, the second bonding portion 314 is bonded to the second obverse surface 122A of the second conductive layer 122. The second bonding portion 314 faces the second obverse surface 122A. The second bonding portion 314 extends in the third direction y. The dimension of the second bonding portion 314 in the third direction y is equal to the dimension of the body 311 in the third direction y.

As shown in FIGS. 13 and 17, the second connecting portion 315 connects the body 311 and the second bonding portion 314. As viewed in the third direction y, the second connecting portion 315 is inclined away from the second obverse surface 122A of the second conductive layer 122 as it approaches the body 311 from the second bonding portion 314. The dimension of the second connecting portion 315 in the third direction y is equal to the dimension of the body 311 in the third direction y.

As shown in FIGS. 17, 18, and 21, the semiconductor device B additionally includes a first conductive bonding layer 33. The first conductive bonding layer 33 is disposed between the second electrode 212 of each first element 21A and the corresponding first bonding portion 312. The first conductive bonding layer 33 electrically joins the second electrode 212 of each first element 21A and the corresponding first bonding portion 312. The first conductive bonding layer 33 may be solder, for example. Alternatively, the first conductive bonding layer 33 may contain sintered metal particles.

As shown in FIG. 17, the semiconductor device B additionally includes a second conductive bonding layer 34. The second conductive bonding layer 34 is disposed between the second obverse surface 122A of the second conductive layer 122 and the second bonding portion 314. The second conductive bonding layer 34 electrically joins the second obverse surface 122A and the second bonding portion 314. The second conductive bonding layer 34 may be solder, for example. Alternatively, the second conductive bonding layer 34 may contain sintered metal particles.

As shown in FIGS. 12 and 19, the second conductive member 32 is electrically bonded to the second electrodes 212 of the respective second elements 21B and the covered portion 15A of the second input terminal 15. Thus, the second electrodes 212 of the second elements 21B are electrically connected to the second input terminal 15. The composition of the second conductive member 32 includes copper. The second conductive member 32 is a metal clip. As shown in FIG. 12, the second conductive member 32 includes a pair of bodies 321, a plurality of third bonding portions 322, a plurality of third connecting portions 323, a pair of fourth bonding portions 324, a pair of fourth connecting portions 325, a plurality of intermediate portions 326, and a plurality of cross beams 327.

As shown in FIG. 12, the bodies 321 are spaced apart from each other in the third direction y. The bodies 321 extend in the second direction x. As shown in FIG. 16, the bodies 321 are disposed parallel to the first obverse surface 121A of the first conductive layer 121 and the second obverse surface 122A of the second conductive layer 122. The bodies 321 are located farther from the first obverse surface 121A and the second obverse surface 122A than the body 311 of the first conductive member 31.

As shown in FIG. 12, the intermediate portions 326 are spaced apart from each other in the third direction y and are located between the two bodies 321 in the third direction y. The intermediate portions 326 extend in the second direction X. The dimension of each intermediate portion 326 in the second direction x is smaller than the dimension of each body 321 in the second direction x.

As shown in FIG. 19, the third bonding portions 322 are electrically bonded to the second electrodes 212 of the respective second elements 21B. Each third bonding portion 322 faces the second electrode 212 of the corresponding second element 21B.

As shown in FIGS. 12 and 20, each third connecting portion 323 is connected to an end of a third bonding portion 322 in the third direction y. Each third connecting portion 323 is also connected to one of the bodies 321 or to one of the intermediate portions 326. As viewed in the second direction x, each third connecting portion 323 is inclined away from the second obverse surface 122A of the second conductive layer 122 as it approaches the corresponding body 321 or intermediate portion 326 from the corresponding third bonding portion 322.

As shown in FIGS. 12 and 16, each fourth bonding portion 324 is bonded to the covered portion 15A of the second input terminal 15. The fourth bonding portions 324 face the covered portion 15A.

As shown in FIGS. 12 and 16, each fourth connecting portion 325 connects a body 321 and a fourth bonding portion 324. As viewed in the third direction y, each fourth connecting portion 325 is inclined away from the first obverse surface 121A of the first conductive layer 121 as it approaches the body 321 from the fourth bonding portion 324.

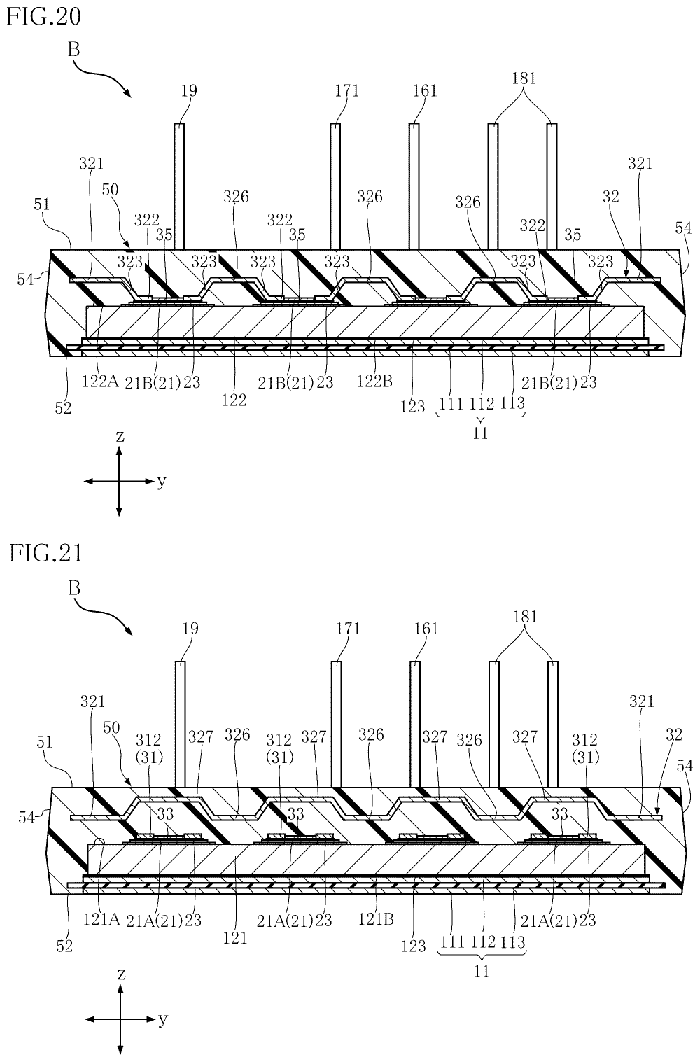

As shown in FIGS. 12 and 21, the cross beams 327 are arranged along the third direction y. As viewed in the first direction z, each cross beam 327 includes a region that overlaps with a first bonding portion 312 of the first conductive member 31. Among the plurality of cross beams 327, each cross beam 327 that is not the outermost one in the third direction y is connected at each end in the third direction y to an intermediate portion 326. Each of the other two cross beams 327 is connected to a body 321 at one end in the third direction y and to an intermediate portion 326 at the other end. As viewed in the second direction x, each cross beam 327 protrudes in the first direction z toward the side that the first obverse surface 121A of the first conductive layer 121 faces.

As shown in FIGS. 17, 19, and 20, the semiconductor device B additionally includes a third conductive bonding layer 35. The third conductive bonding layer 35 is disposed between the second electrode 212 of each second element 21B and the corresponding third bonding portion 322. The third conductive bonding layer 35 electrically joins the second electrode 212 of each second element 21B and the corresponding third bonding portion 322. The third conductive bonding layer 35 may be solder, for example. Alternatively, the third conductive bonding layer 35 may contain sintered metal particles.

As shown in FIG. 16, the semiconductor device B additionally includes a fourth conductive bonding layer 36. The fourth conductive bonding layer 36 is disposed between the covered portion 15A of the second input terminal 15 and each fourth bonding portion 324. The fourth conductive bonding layer 36 electrically joins the covered portion 15A and each fourth bonding portion 324. The fourth conductive bonding layer 36 may be solder, for example. Alternatively, the fourth conductive bonding layer 36 may contain sintered metal particles.

As shown in FIGS. 16, 17, 20, and 21, the sealing resin 50 covers the first conductive layer 121, the second conductive layer 122, the semiconductor elements 21, the first conductive member 31, and the second conductive member 32. The sealing resin 50 also covers a portion of each of the substrate 11, the first input terminal 13, the output terminal 14, and the second input terminal 15. The sealing resin 50 is electrically insulating. The sealing resin 50 is made of a material containing a black epoxy resin, for example. As shown in FIGS. 10 and 14 to 17, the sealing resin 50 has a top surface 51, a bottom surface 52, a pair of first side surfaces 53, a pair of second side surfaces 54, and a pair of recessed portions 55.

As shown in FIGS. 16 and 17, the top surface 51 faces the same side as the first obverse surface 121A of the first conductive layer 121 in the first direction z. As shown in FIGS. 16 and 17, the bottom surface 52 faces away from the top surface 51 in the first direction z. As shown in FIG. 15, the heat dissipating layer 113 of the substrate 11 is exposed from the bottom surface 52.

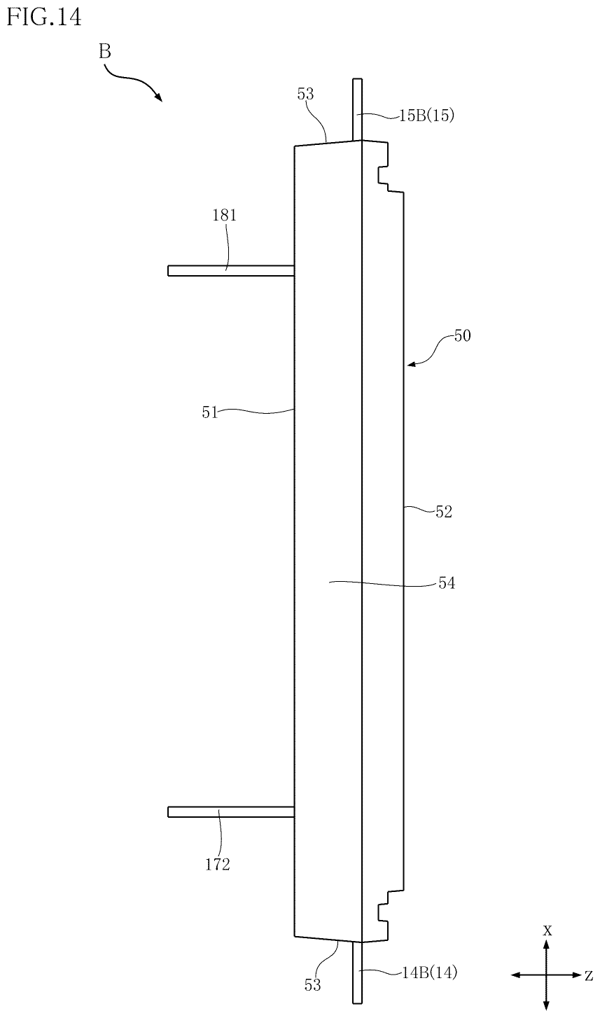

As shown in FIGS. 10 and 14, the first side surfaces 53 are spaced apart from each other in the second direction x. Each first side surface 53 faces in the second direction x and extends in the third direction y. Each first side surface 53 is connected to the top surface 51. The exposed portion 13B of the first input terminal 13 and the exposed portion 15B of the second input terminal 15 protrude from one of the first side surfaces 53. The exposed portion 14B of the output terminal 14 protrudes from the other first side surface 53.

As shown in FIGS. 10 and 15, the second side surfaces 54 are spaced apart from each other in the third direction y. The second side surfaces 54 face away from each other in the third direction y and extend in the second direction x. Each second side surface 54 is connected to the top surface 51 and the bottom surface 52.

As shown in FIGS. 10 and 15, the pair of recessed portions 55 are recessed in the second direction x from the first side surface 53 from which the exposed portion 13B of the first input terminal 13 and the exposed portion 15B of the second input terminal 15 protrude. Each recessed portion 55 extends in the first direction z from the top surface 51 to the bottom surface 52. The recessed portions 55 are located on the opposite sides of the first input terminal 13 in the third direction y.

### First Embodiment (Cooling Structure for Semiconductor Device)

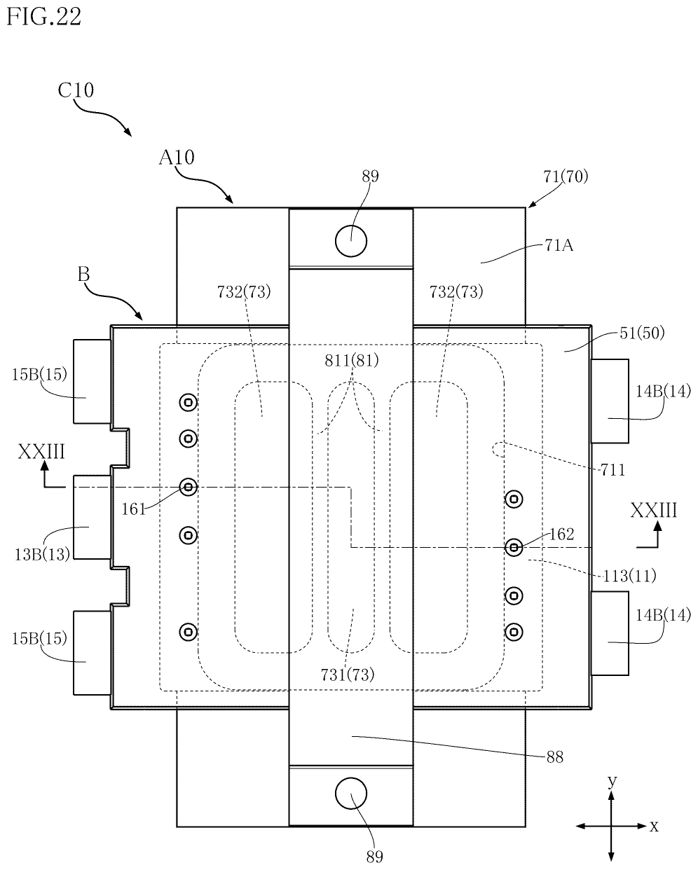

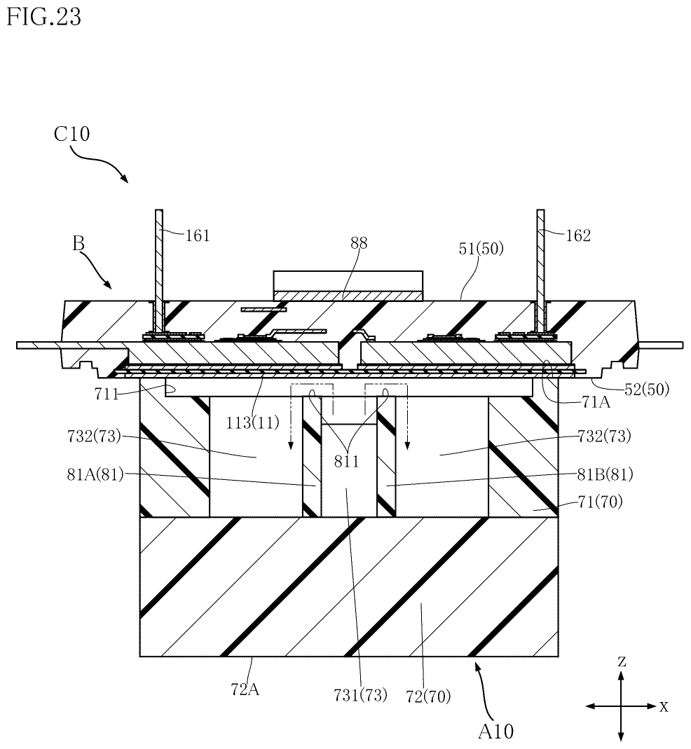

Next, with reference to FIGS. 22 and 23, the following describes a cooling structure C10 according to the first embodiment of the present disclosure (hereinafter “cooling structure C10”). The cooling structure C10 includes a cooler A10, a semiconductor device B, and a mounting member 88. The cooling structure C10 may be a portion of an inverter device that drives a three-phase AC motor, for example. FIG. 22 shows the XXIII-XXIII with a dot-dash line.

As shown in FIGS. 22 and 23, the semiconductor device B of the cooling structure C10 is attached to the obverse surface 71A of the housing 70 of the cooler A10. The semiconductor device B closes the opening 711 of the housing 70. More specifically, as shown in FIG. 23, the semiconductor device B is disposed to close the opening 711 with the heat dissipating layer 113 of the substrate 11. The semiconductor device B is in contact with the obverse surface 71A at the bottom surface 52 of the sealing resin 50.

As shown in FIGS. 22 and 23, the mounting member 88 secures the semiconductor device B to the housing 70 of the cooler A10. The mounting member 88 is made of a material containing metal. The mounting member 88 is disposed in contact with the top surface 51 of the sealing resin 50 of the semiconductor device B, extending across the top surface 51. The mounting member 88 may be a leaf spring, for example. The mounting member 88 is located between the first signal terminal 161 and the second signal terminal 162 of the semiconductor device B in the second direction x. The mounting member 88 is fastened to the housing 70 at each end in the third direction y using a fastening member 89. The fastening members 89 may be bolts, for example.

Next, advantages of the cooler A10 and the cooling structure C10 will be described.

The cooler A10 includes the housing 70 and the partition wall 81. The housing 70 includes: the opening 711 on the first side in the first direction z; the internal space 73 connected to the opening 711; and the bottom 72 located opposite the opening 711 with respect to the internal space 73. The internal space 73 includes the first reservoir 731 and the second reservoir 732 that are partitioned by the partition wall 81. The partition wall 81 includes the overflow section 811 that overlaps with the opening 711 as viewed in the first direction z and that is a portion farthest from the bottom 72 of the housing 70. The overflow section 811 is located between the bottom 72 and the opening 711.

With this configuration, as the coolant is fed into the first reservoir 731 through the inlet channel 74, the liquid level of the coolant rises toward the overflow section 811. When the liquid level exceeds the overflow section 811, the coolant flows over the overflow section 811 and then down into the second reservoir 732. This reduces the interference of the internal space 73 with the flow direction of the coolant. In addition, the hydraulic head of the coolant increases between the inlet channel 74 and the overflow section 811, which reduces the total energy losses. In this way, the cooler A10 facilitates the distribution of coolant to the entire target to be cooled.

In the cooling structure C10, the semiconductor device B closes the opening 711. In the cooler A10, the overflow section 811 is spaced apart from the opening 711 in the first direction z. With this configuration, the cooling structure C10 is provided with a gap between the overflow section 811 and the semiconductor device B in the first direction z. The gap allows the coolant to flow over the overflow section 811 (see the arrows in FIG. 23). In the cooling structure C10, the coolant flowing through the gap comes into contact with the semiconductor device B and cools the semiconductor device B. The coolant contacting the semiconductor device B flows in a direction orthogonal to the first direction z. That is, the semiconductor device B in the cooling structure C10 is arranged to reduce the interference of with the flow of coolant. That is, the cooler A10 and the cooling structure C10 of the configuration described above improve the cooling efficiency while reducing energy losses in the coolant flow.

The partition wall 81 overlaps with the opening 711 of the housing 70 as viewed in the first direction z, and includes the first partition wall 81A and the second partition wall 81B that are spaced apart from each other in the second direction x. The first reservoir 731 is located between the first partition wall 81A and the second partition wall 81B. As viewed in the first direction z, the first reservoir 731 overlaps with the center C of the opening 711. With this configuration, the coolant is directed outward in the second direction x from the center C and flows over the overflow section 811 of the partition wall 81. This reduces the unevenness in the flow of coolant that comes into contact with the semiconductor device B.

In the case described above, the first partition wall 81A and the second partition wall 81B extend in the third direction y. Suppose that the semiconductor device B to be cooled includes a plurality of semiconductor elements 21 arranged along the third direction y, the cooling structure C10 of this configuration efficiently reduces the uneven distribution of heat in the semiconductor device B caused by the semiconductor elements 21.

The inlet channel 74 and the outlet channel 75 are disposed at the bottom 72. Each of the inlet channel 74 and the outlet channel 75 penetrates the bottom 72 in the first direction z. This configuration achieves a higher hydraulic head of the coolant in the first reservoir 731 without requiring an increase in the dimension of the cooling structure C10 in a direction orthogonal to the first direction z. This further reduces the total energy losses in the flow of coolant within the first reservoir 731.

The body 71 of the housing 70 and the partition wall 81 are made of a material containing resin. In addition, the partition wall 81 is integral with the body 71. With this configuration, the cooler A10 can be lighter and more rigid.

### Second Embodiment (Cooler)

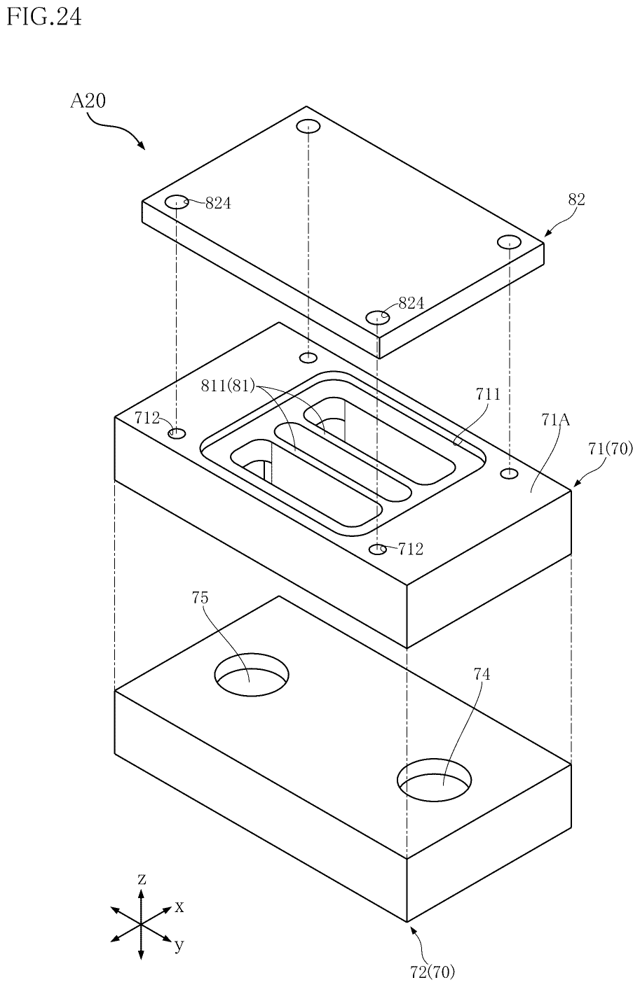

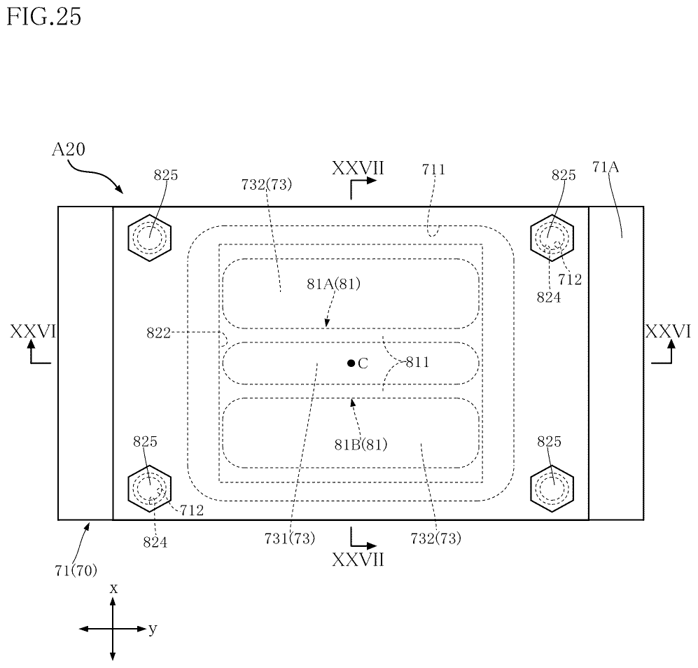

With reference to FIGS. 24 to 28, a cooler A20 according to a second embodiment of the present disclosure is described. In these figures, elements that are identical or similar to those of the cooler A10 described above are indicated by the same reference numerals, and overlapping descriptions are omitted.

Unlike the cooler A10, the cooler A20 additionally includes a lid member 82.

As shown in FIGS. 24 to 27, the lid member 82 closes the opening 711 of the housing 70. The body 71 of the housing 70 has a plurality of mounting holes 712 that are recessed from the obverse surface 71A. The lid member 82 has a plurality of through-holes 824 penetrating the lid member 82 in the first direction z. As viewed in the first direction z, the through-holes 824 overlap with the respective mounting holes 712. A fastening member 825 is inserted through each through-hole 824 and a corresponding mounting hole 712 to secure the lid member 82 to the body 71. The fastening members 825 may be bolts, for example. The lid member 82 is made of a material containing metal. The lid member 82 has a higher thermal conductivity than both the body 71 and the partition wall 81.

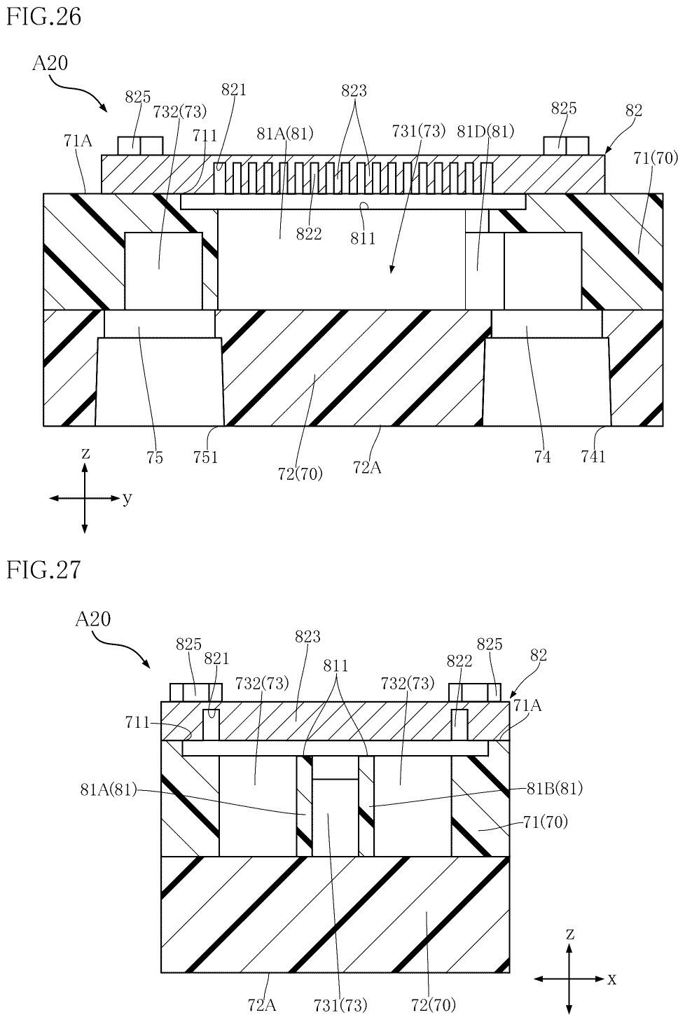

As shown in FIGS. 26 and 27, the lid member 82 has a base surface 821 facing the opening 711 of the housing 70. The base surface 821 is spaced apart from the overflow section 811 of the partition wall 81. That is, the cooler A20 has a gap between the overflow section 811 and the base surface 821.

As shown in FIGS. 26 to 28, the lid member 82 has a depressed section 822 that is recessed in the first direction z. The depressed section 822 has a part defined by the base surface 821. Thus, the depressed section 822 faces the opening 711 of the housing 70.

As shown in FIGS. 26 to 28, the lid member 82 includes a heat-dissipating section 823 that protrudes from the base surface 821. The heat-dissipating section 823 is accommodated in the depressed section 822. In the cooler A20, the heat-dissipating section 823 is spaced apart from the overflow section 811 of the partition wall 81.

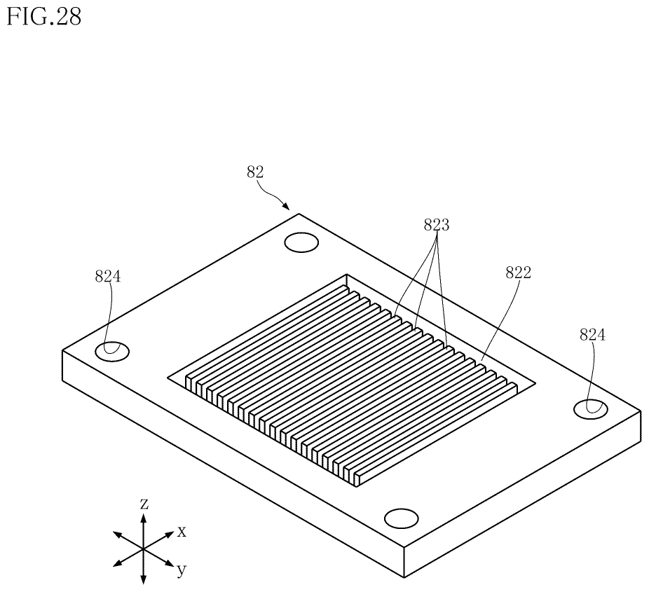

As shown in FIG. 28, the heat-dissipating section 823 includes a plurality of fins each extending in the second direction x. The fins are arranged along the third direction y. Thus, as viewed in first direction z, each fin is orthogonal to the first partition wall 81A and the second partition wall 81B of the partition wall 81. Alternatively, the heat-dissipating section 823 may include a plurality of pins spaced apart from each other in a direction orthogonal to the first direction z.

### Second Embodiment (Cooling Structure for Semiconductor Device)

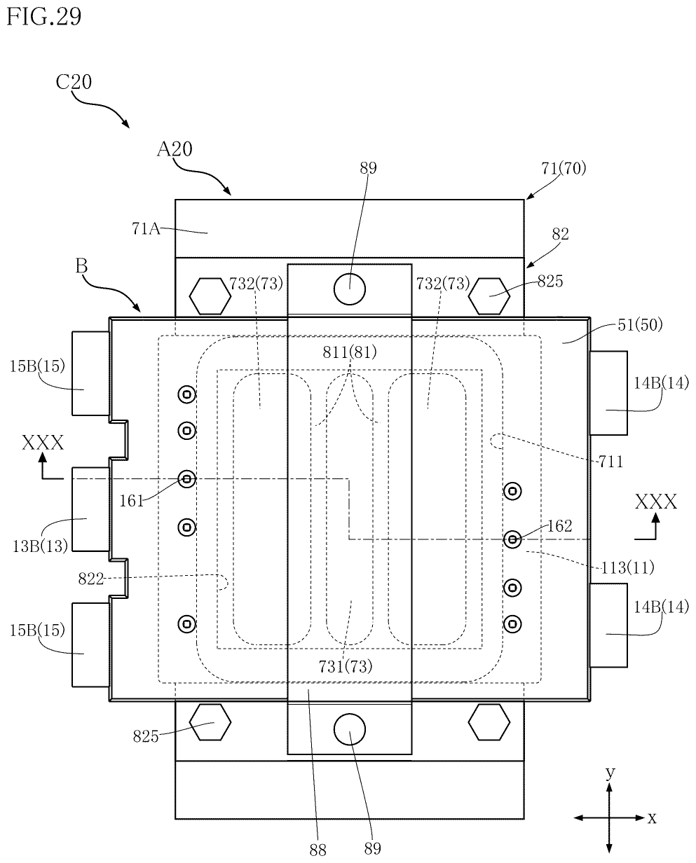

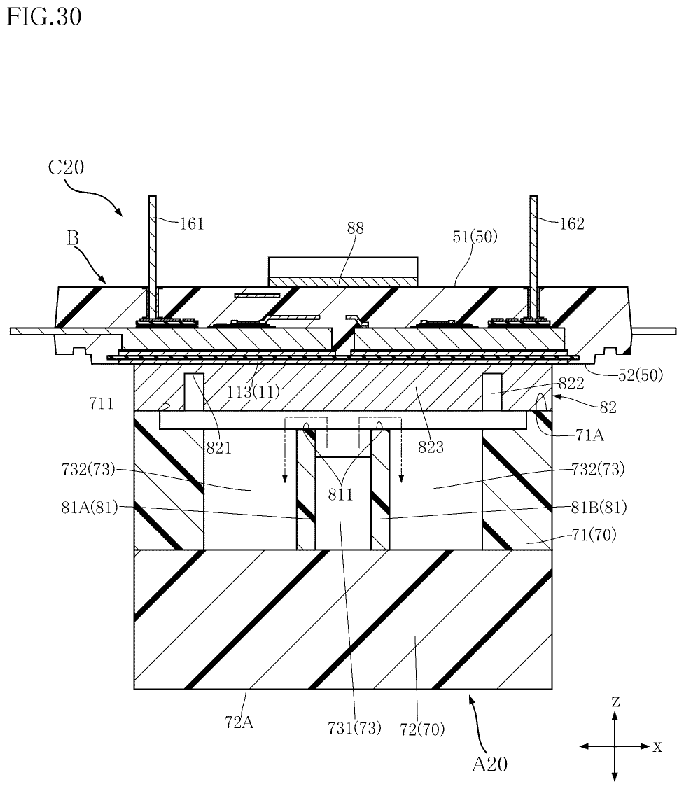

Next, with reference to FIGS. 29 and 30, the following describes a cooling structure C20 according to the second embodiment of the present disclosure (hereinafter “cooling structure C20”). In these figures, elements that are identical or similar to those of the cooling structure C10 described above are indicated by the same reference numerals, and overlapping descriptions are omitted. FIG. 29 shows the XXX-XXX with a dot-dash line.

The cooling structure C20 includes a cooler A20, a semiconductor device B, and a mounting member 88. As shown in FIGS. 29 and 30, the semiconductor device B of the cooling structure C20 is attached to the lid member 82 of the cooler A20. The semiconductor device B is in contact with the lid member 82 at the heat dissipating layer 113 of the substrate 11 and the bottom surface 52 of the sealing resin 50. As viewed in the first direction z, the substrate 11 of the semiconductor device B overlaps with the opening 711 of the housing 70.

As shown in FIG. 29, the mounting member 88 is fastened to the lid member 82 at each end in the third direction y using a fastening member 89.

Next, advantages of the cooler A20 and the cooling structure C20 will be described.

The cooler A20 includes the housing 70 and the partition wall 81. The housing 70 includes: the opening 711 on the first side in the first direction z; the internal space 73 connected to the opening 711; and the bottom 72 located opposite the opening 711 with respect to the internal space 73. The internal space 73 includes the first reservoir 731 and the second reservoir 732 that are partitioned by the partition wall 81. The partition wall 81 includes the overflow section 811 that overlaps with the opening 711 as viewed in the first direction z and that is a portion farthest from the bottom 72 of the housing 70. The overflow section 811 is located between the bottom 72 and the opening 711. With this configuration, the cooler A20 reduces energy losses in the coolant flow and thus facilitates the distribution of coolant to the entire target to be cooled.

The cooler A20 additionally includes the lid member 82 that has the base surface 821 facing the opening 711 and closing the opening 711. The overflow section 811 is spaced apart from the base surface 821. With this configuration, the cooler A20 is provided with a gap between the overflow section 811 and the base surface 821. The gap allows the coolant to flow over the overflow section 811 (see the arrows in FIG. 30). In addition, the semiconductor device B of the cooling structure C20 is attached to the lid member 82. As viewed in the first direction z, the semiconductor device B overlaps with the opening 711. With this configuration of the cooling structure C20, the coolant comes into contact with the lid member 82 and cools the semiconductor device B via the lid member 82. In the cooling structure C20, the semiconductor device B does not contact the coolant and thus does not interfere with the flow of coolant. The cooler A20 and the cooling structure C20 of the configuration described above therefore improve the cooling efficiency while reducing energy losses in the coolant flow.

The lid member 82 of the cooler A20 has the depressed section 822 that is recessed in the first direction z and that is partly defined by the base surface 821. The lid member 82 includes the heat-dissipating section 823 that protrudes from the base surface 821. The heat-dissipating section 823 is accommodated in the depressed section 822. With this configuration, a gap is provided between the overflow section 811 of the partition wall 81 and the base surface 821 such that coolant flows through the gap while making contact with the heat-dissipating section 823. This efficiently improves the cooling efficiency of the cooler A20.

The heat-dissipating section 823 of the lid member 82 includes the plurality of fins each extending in the second direction x. The fins are arranged along the third direction y. This configuration prevents the heat-dissipating section 823 from interfering with the flow of coolant that flows over the overflow section 811 of the partition wall 81. In addition, the heat-dissipating section 823 of this configuration increases the surface area that contacts the coolant and further improves the cooling efficiency of the cooler A20.

The cooler A30 has a configuration in common with the cooler A10, thereby achieving the same effect as the cooler A10.

### Third Embodiment (Cooler)

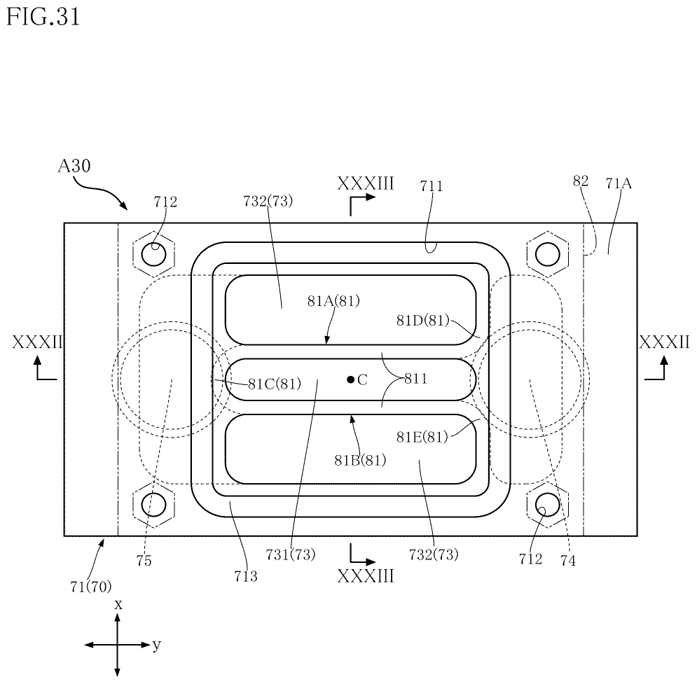

With reference to FIGS. 31 to 33, a cooler A30 according to a third embodiment of the present disclosure is described. In these figures, elements that are identical or similar to those of the coolers A10 and A20 described above are indicated by the same reference numerals, and overlapping descriptions are omitted. For the convenience of description, FIG. 31 shows the lid member 82 as transparent. In FIG. 31, the outline of the lid member 82 is indicated by an imaginary line.

The cooler A30 differs from the cooler A20 in the configurations of the partition wall 81 and the body 71 of the housing 70.

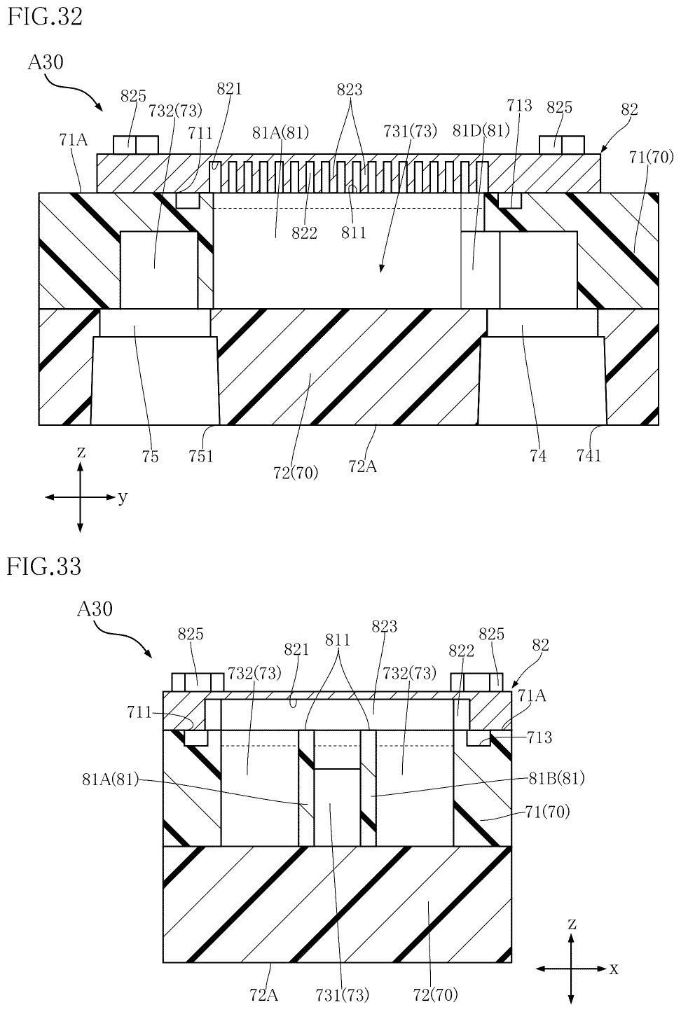

As shown in FIGS. 32 and 33, the overflow section 811 of the partition wall 81 and the opening 711 of the housing 70 are located at the same position in the first direction z. That is, the overflow section 811 is flush with the obverse surface 71A of the housing 70.

As shown in FIGS. 31 to 33, the body 71 of the housing 70 has a groove 713 that is recessed from the obverse surface 71A. The groove 713 is a portion of the opening 711 in the housing 70. The portion of the partition wall 81 exposed from the opening 711 is surrounded by the groove 713.

As shown in FIGS. 32 and 33, the heat-dissipating section 823 of the lid member 82 is in contact with the overflow section 811 of the partition wall 81. However, the base surface 821 of the lid member 82 is spaced apart from the overflow section 811. That is, the cooler A30 has a gap between the overflow section 811 and the base surface 821.

Next, advantages of the cooler A30 will be described.

The cooler A30 includes the housing 70 and the partition wall 81. The housing 70 includes: the opening 711 on the first side in the first direction z; the internal space 73 connected to the opening 711; and the bottom 72 located opposite the opening 711 with respect to the internal space 73. The internal space 73 includes the first reservoir 731 and the second reservoir 732 that are partitioned by the partition wall 81. The partition wall 81 includes the overflow section 811 that overlaps with the opening 711 as viewed in the first direction z and that is a portion farthest from the bottom 72 of the housing 70. The overflow section 811 is located between the bottom 72 and the opening 711. With this configuration, the cooler A30 reduces energy losses in the coolant flow and thus facilitates the distribution of coolant to the entire target to be cooled.

The cooler A30 additionally includes the lid member 82 that has the base surface 821 facing the opening 711 and closing the opening 711. The overflow section 811 is spaced apart from the base surface 821. With this configuration, the cooler A30 is provided with a gap between the overflow section 811 and the base surface 821. The gap allows the coolant to flow over the overflow section 811 while making contact with the lid member 82. That is, the cooler A30 of the configuration described above improves the cooling efficiency while reducing energy losses in the coolant flow.

In the cooler A30, the heat-dissipating section 823 of the lid member 82 is in contact with the overflow section 811 of the partition wall 81. This configuration ensures that the coolant flowing over the overflow section 811 makes contact with the heat-dissipating section 823 over a greater surface area. The cooler A30 thus further improves its cooling efficiency.

The cooler A30 has a configuration in common with the cooler A10, thereby achieving the same effect as the cooler A10. The cooling structure C20 described above may include the cooler A30 in place of the cooler A20.

### Fourth Embodiment (Cooler)

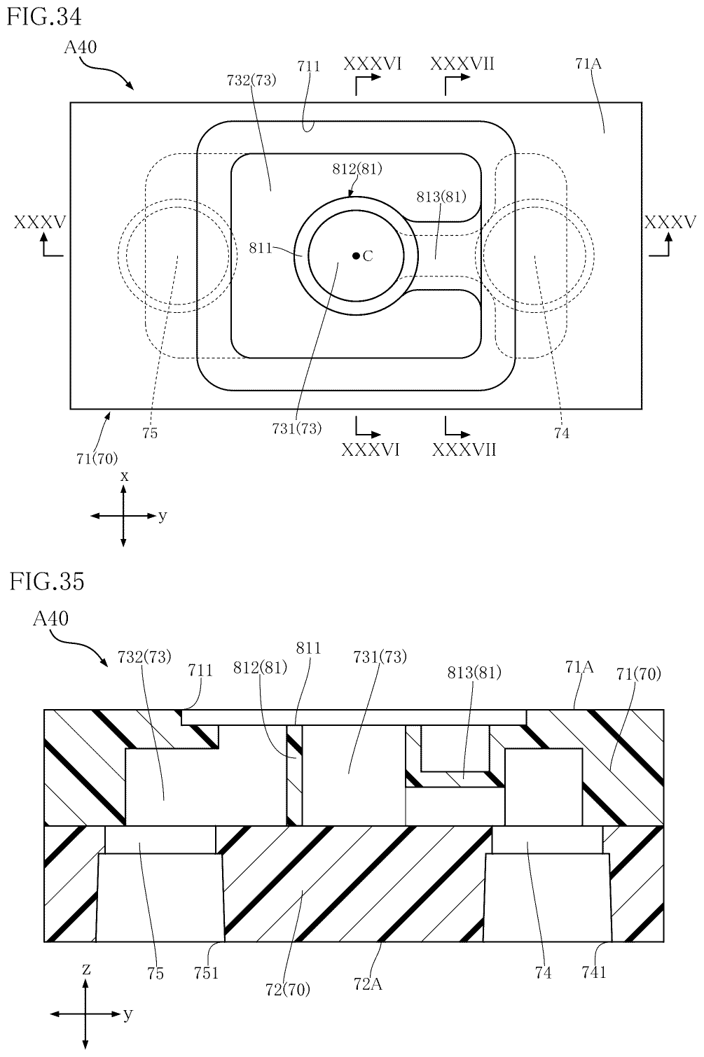

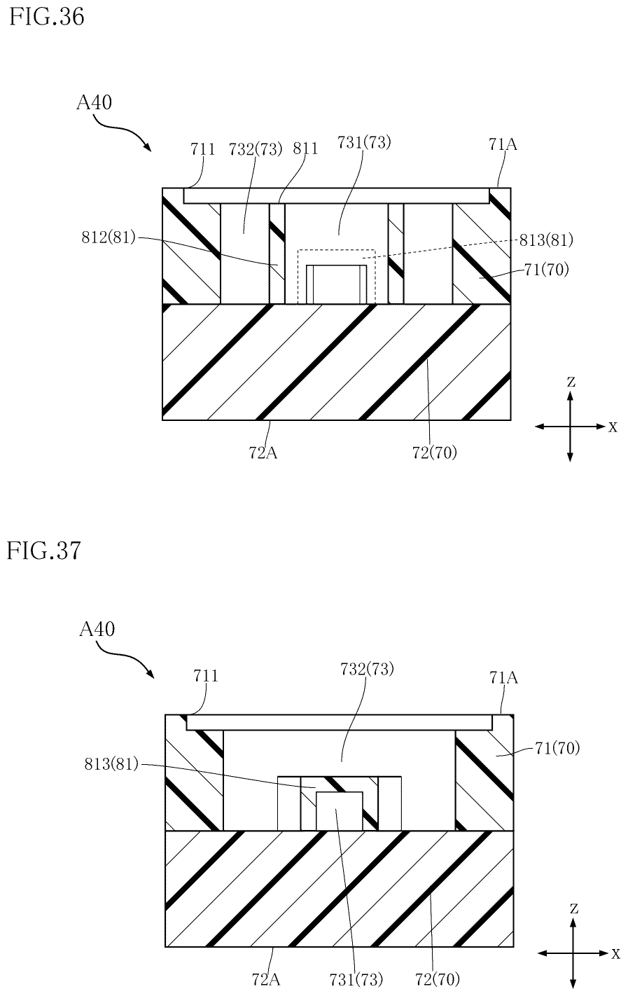

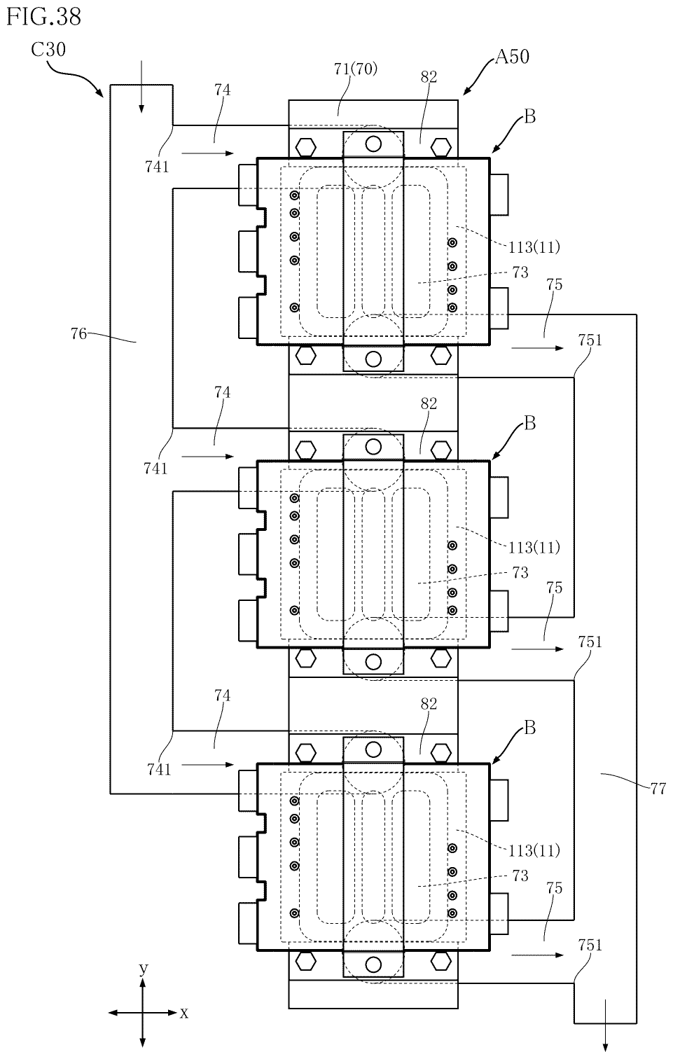

With reference to FIGS. 34 to 37, a cooler A40 according to a fourth embodiment of the present disclosure is described. In these figures, elements that are identical or similar to those of the cooler A10 described above are indicated by the same reference numerals, and overlapping descriptions are omitted.

The cooler A40 differs from the cooler A10 in the configurations of the partition wall 81 and the internal space 73 of the housing 70.

As shown in FIGS. 34 and 35, the partition wall 81 includes an annular portion 812 and a cover portion 813, in place of the first partition wall 81A, the second partition wall 81B, the third partition wall 81C, the fourth partition wall 81D, and the fifth partition wall 81E. As viewed in the first direction z, the annular portion 812 surrounds the center C of the opening 711 of the housing 70. In the cooler A40, the annular portion 812 has an overflow section 811.

As shown in FIGS. 34 and 35, the cover portion 813 connects the annular portion 812 and the body 71 of the housing 70. As shown in FIGS. 35 to 37, the cover portion 813 is spaced apart from the overflow section 811 in the first direction z.

As shown in FIG. 34, the second reservoir 732 surrounds the first reservoir 731 as viewed in first direction z. As viewed in the first direction z, the second reservoir 732 overlaps with the cover portion 813. A portion of the first reservoir 731 is enclosed between the bottom 72 of the housing 70 and the cover portion 813.

Next, advantages of the cooler A40 will be described.

The cooler A40 includes the housing 70 and the partition wall 81. The housing 70 includes: the opening 711 on the first side in the first direction z; the internal space 73 connected to the opening 711; and the bottom 72 located opposite the opening 711 with respect to the internal space 73. The internal space 73 includes the first reservoir 731 and the second reservoir 732 that are partitioned by the partition wall 81. The partition wall 81 includes the overflow section 811 that overlaps with the opening 711 as viewed in the first direction z and that is a portion farthest from the bottom 72 of the housing 70. The overflow section 811 is located between the bottom 72 and the opening 711. With this configuration, the cooler A40 reduces energy losses in the coolant flow and thus facilitates the distribution of coolant to the entire target to be cooled.

In the cooler A40, the overflow section 811 is spaced apart from the opening 711 in the first direction z. With this configuration, the cooling structure C10 described above may include the cooler A40 in place of the cooler A10. Even so, the cooling structure C10 is still provided with a gap between the overflow section 811 and the semiconductor device B in the first direction z. The gap allows the coolant to flow over the overflow section 811. That is, the cooler A40 of the configuration described above improves the cooling efficiency while reducing energy losses in the coolant flow.

In the cooler A40, the second reservoir 732 surrounds the first reservoir 731 as viewed in the first direction z. In addition, the first reservoir 731 overlaps with the center C of the opening 711 of the housing 70 as viewed in the first direction z. With this configuration, the coolant is directed radially as viewed in the first direction z and flows over the overflow section 811 of the partition wall 81. This further reduces the unevenness in the flow of coolant that comes into contact with the semiconductor device B.

In the cooler A40, the cover portion 813 of the partition wall 81 is spaced apart from the overflow section 811 of the partition wall 1 in the first direction Z. This configuration makes it possible to arrange the second reservoir 732 to surround the first reservoir 731 as viewed in the first direction z.

The cooler A40 has a configuration in common with the cooler A10, thereby achieving the same effect as the cooler A10. As already mentioned, the cooling structure C10 may include the cooler A40 in place of the cooler A10. Further, the cooler A40 may be provided with a lid member 82 similar to that of the cooler A20 described above.

### Third Embodiment (Cooling Structure for Semiconductor Device)

Next, with reference to FIG. 38, the following describes the cooling structure C30 according to the third embodiment of the present disclosure (hereinafter “cooling structure C30”). In these figures, elements that are identical or similar to those of the cooling structures C10 and C20 described above are indicated by the same reference numerals, and overlapping descriptions are omitted.

The cooling structure C30 includes a cooler A50, a plurality of semiconductor devices B, a plurality of mounting members 88, a branching channel 76, and a merging channel 77.

The cooler A50 is composed of a plurality of coolers A20 that are arranged along the third direction y with their housings 70 joined together. Alternatively, the cooler A50 may be composed of any of coolers A10, A30 or A40 that are arranged along the third direction y with their housings 70 joined together.

The cooler A50 thus includes a plurality of internal spaces 73 arranged along the direction orthogonal to the first direction z as shown in FIG. 38. Each internal space 73 is recessed in the first direction z.

As shown in FIG. 38, each semiconductor device B is secured to a corresponding one of the lid members 82 of the cooler A50 using a mounting member 88. As viewed in the first direction z, the semiconductor devices B overlap with the respective internal spaces 73.

The cooler A50 is provided with a plurality of inlet channels 74 and a plurality of outlet channels 75 at the bottoms 72 of the respective housings 70. Each inlet channel 74 and each inlet channel 74 is extended to the outside from the corresponding bottom 72. Each inlet channel 74 is connected to a corresponding internal space 73. Each outlet channel 75 is connected to a corresponding internal space 73.

As shown in FIG. 38, the branching channel 76 is connected to the inlets 741 of the respective inlet channels 74. As shown in FIG. 38, the merging channel 77 is connected to the outlets 751 of the respective outlet channels 75.

FIG. 38 shows the arrows indicating the flow of coolant in the cooling structure C30. The coolant that is fed from the outside into the branching channel 76 flows through the inlet channels 74 and then into the internal spaces 73. The coolant that flows into the internal spaces 73 then flows through the outlet channels 75 into the merging channel 77. The coolant that flows into the merging channel 77 is discharged to the outside. That is, the outlet channels 75 of the respective coolers A50 are designed as a system that is separate from any of the inlet channels 74. Thus, in the cooling structure C30, the coolant flowing through the outlet channels 75 is not circulated back into the inlet channels 74.

Next, advantages of the cooling structure C30 will be described.

The cooling structure C30 includes: the cooler A50 having the plurality of internal spaces 73; and the plurality of semiconductor devices B attached to the cooler A50. As viewed in the first direction z, the semiconductor devices B overlap with the respective internal spaces 73. The cooler A50 includes the plurality of inlet channels 74 and the plurality of outlet channels 75 that are configured as a system separate from the inlet channels 74. The inlet channels 74 are individually connected to the internal spaces 73. The outlet channels 75 are individually connected to the internal spaces 73. With this configuration, the coolant flows in and out of the internal spaces 73 through a plurality of parallel flow paths. This ensures that the coolant in the respective internal spaces 73 has a relatively low and uniform temperature. This improves the cooling efficiency of the semiconductor devices B. In addition, this configuration reduces energy losses because the coolant flowing through the parallel flow paths undergoes fewer abrupt changes in cross-sectional area than the coolant flowing through the path serially connecting the internal spaces 73. That is, the cooling structure C30 of the configuration described above improves the cooling efficiency while reducing energy losses in the coolant flow.

The present disclosure is not limited to the embodiments described above. Various modifications in design may be made freely in the specific structure of each part of the present disclosure.

The present disclosure include embodiments described in the following clauses.

### Clause 1.

A cooler comprising:

a housing that includes an opening located on a first side in a first direction, an internal space connected to the opening, and a bottom located opposite the opening with respect to the internal space and defining a portion of the internal space; and

a partition wall that rises in the first direction from the bottom and that is accommodated in the internal space,

wherein the housing includes an inlet channel and an outlet channel that are connected to the internal space,

the internal space includes a first reservoir and a second reservoir that are partitioned by the partition wall,

the first reservoir is connected to the inlet channel,

the second reservoir is connected to the outlet channel,

the partition wall includes an overflow section that overlaps with the opening as viewed in the first direction and is farthest from the bottom, and

the overflow section is located between the bottom and the opening.

### Clause 2.

The cooler according to Clause 1, wherein the overflow section is spaced apart from the opening in the first direction.

### Clause 3.

The cooler according to Clause 1 or 2, further comprising a lid member that includes a base surface facing the opening and that closes the opening,

wherein the overflow section is spaced apart from the base surface.

### Clause 4.

The cooler according to Clause 2 or 3, wherein the second reservoir surrounds the first reservoir as viewed in the first direction.

### Clause 5.

The cooler according to Clause 3, wherein the partition wall includes a first wall and a second wall that overlap with the opening as viewed in the first direction and that are spaced apart from each other in a second direction orthogonal to the first direction, and

either the first reservoir or the second reservoir is located between the first wall and the second wall.

### Clause 6.

The cooler according to Clause 5, wherein each of the first wall and the second wall extends in a third direction orthogonal to the first direction and the second direction.

### Clause 7.

The cooler according to Clause 6, wherein the first reservoir is located between the first wall and the second wall.

### Clause 8.

The cooler according to Clause 7, wherein the first reservoir overlaps with a center of the opening as viewed in the first direction.

### Clause 9.

The cooler according to any one of Clauses 2 to 8, wherein the inlet channel and the outlet channel are disposed at the bottom, and

each of the inlet channel and the outlet channel penetrates the bottom in the first direction.

### Clause 10.

The cooler according to any one of Clauses 2 to 9, wherein the housing includes a body that includes the opening and that defines a portion of the internal space, and

the bottom is attached to the body.

### Clause 11.

The cooler according to any one of Clauses 2 to 10, wherein the body and the partition wall are made of a material containing resin.

### Clause 12.

The cooler according to Clause 11, wherein the partition wall is integral with the body.

### Clause 13.

The cooler according to any one of Clauses 6 to 8, wherein the lid member includes a depressed section that is depressed in the first direction and that includes a portion defined by the base surface,

the lid member includes a heat-dissipating section protruding from the base surface, and

the heat-dissipating section is accommodated in the depressed section.

### Clause 14.

The cooler according to Clause 13, wherein the heat-dissipating section includes a plurality of fins each extending in the second direction, and

the fins are arranged along the third direction.

### Clause 15.

A cooling structure for a semiconductor device, the cooling structure comprising:

the cooler according to Clause 2, and

a semiconductor device attached to the cooler,

wherein the semiconductor device is attached to the housing, and

the semiconductor device closes the opening.

### Clause 16.

The cooling structure according to Clause 15, wherein the semiconductor device includes a substrate, a conductive layer supported on the substrate, and a semiconductor element that is located opposite the substrate with respect to the conductive layer and bonded to the conductive layer, and

the substrate closes the opening.

### Clause 17.

A cooling structure for a semiconductor device, the cooling structure comprising:

the cooler according to Clause 3, and

a semiconductor device attached to the cooler,

wherein the semiconductor device is attached to the lid member, and

the semiconductor device overlaps with the opening as viewed in the first direction.

### Clause 18.

A cooling structure for a semiconductor device, the cooling structure comprising:

a cooler including a plurality of internal spaces each recessed in a first direction, the plurality of internal spaces being arranged along a direction orthogonal to the first direction; and

a plurality of semiconductor devices attached to the cooler,

wherein the plurality of semiconductor devices individually overlap with the plurality of internal spaces as viewed in the first direction,

the cooler includes a plurality of inlet channels and a plurality of outlet channels that are configured as a system separate from the plurality of inlet channels,

the plurality of inlet channels are individually connected to the plurality of internal spaces, and

the plurality of outlet channels are individually connected to the plurality of internal spaces.

REFERENCE NUMERALS

| | |
|---|---|
| A10, A20, A30, A40, A50: cooler | |
| B: semiconductor device | C10, C20, C30: cooling structure |
| 11: substrate | 111: insulating layer |
| 112: intermediate layer | 113: heat dissipating layer |
| 121: first conductive layer | 121A: first obverse surface |
| 121B: first reverse surface | 122: second conductive layer |
| 122A: second obverse surface | 122B: second reverse surface |
| 123: first adhesive layer | 13: first input terminal |
| 13A: covered portion | 13B: exposed portion |
| 14: output terminal | 14A: covered portion |
| 14B: exposed portion | 15: second input terminal |
| 15A: covered portion | 15B: exposed portion |
| 161: first signal terminal | 162: second signal terminal |
| 171: third signal terminal | 172: fourth signal terminal |
| 181: fifth signal terminal | 182: sixth signal terminal |
| 19: seventh signal terminal | 21: semiconductor element |
| 21A: first element | 21B: second element |
| 211: first electrode | 212: second electrode |
| 213: third electrode | 214: fourth electrode |
| 22: thermistor | 23: conductive bonding layer |
| 31: first conductive member | 311: body |
| 312: first bonding portion | 313: first connecting portion |
| 314: second bonding portion | 315: second connecting portion |
| 32: second conductive member | 321: body |
| 322: third bonding portion | 323: third connecting portion |
| 324: fourth bonding portion | 325: fourth connecting portion |
| 326: intermediate portion | 327: cross beam |
| 33: first conductive bonding layer | |
| 34: second conductive bonding layer | |
| 35: third conductive bonding layer | |
| 36: fourth conductive bonding layer | |
| 41: first wire | 42: second wire |
| 43: third wire | 44: fourth wire |
| 50: sealing resin | 51: top surface |
| 52: bottom surface | 53: first side surface |
| 54: second side surface | 55: recessed portion |
| 60: control wiring | 601: first wiring |
| 602: second wiring | 61: insulating layer |
| 62: wiring layer | 621: first wiring layer |
| 622: second wiring layer | 623: third wiring layer |
| 624: fourth wiring layer | 625: fifth wiring layer |
| 63: metal layer | 64: sleeve |
| 641: end surface | 68: second adhesive layer |
| 69: third adhesive layer | 70: housing |
| 71: body | 71A: obverse surface |
| 711: opening | 712: mounting hole |
| 713: groove | 72: bottom |
| 72A: reverse surface | 73: internal space |
| 731: first reservoir | 732: second reservoir |
| 74: inlet channel | 741: inlet |
| 75: outlet channel | 751: outlet |
| 76: branching channel | 77: merging channel |
| 81: partition wall | 81A: first partition wall |
| 81B: second partition wall | 81C: third partition wall |
| 81D: fourth partition wall | 81E: fifth partition wall |
| 811: overflow section | 812: annular portion |
| 813: cover portion | 82: lid member |
| 821: base surface | 822: depressed section |
| 823: heat-dissipating section | 824: through-hole |
| 825: fastening member | 88: mounting member |
| 89: fastening member | z: first direction |
| x: second direction | y: third direction |

1. A cooler comprising:
a housing that includes an opening located on a first side in a first direction, an internal space connected to the opening, and a bottom located opposite the opening with respect to the internal space and defining a portion of the internal space; and
a partition wall that rises in the first direction from the bottom and that is accommodated in the internal space,
wherein the housing includes an inlet channel and an outlet channel that are connected to the internal space,
the internal space includes a first reservoir and a second reservoir that are partitioned by the partition wall,
the first reservoir is connected to the inlet channel,
the second reservoir is connected to the outlet channel,
the partition wall includes an overflow section that overlaps with the opening as viewed in the first direction and is farthest from the bottom, and
the overflow section is located between the bottom and the opening.

2. The cooler according to claim 1, wherein the overflow section is spaced apart from the opening in the first direction.

3. The cooler according to claim 1, further comprising a lid member that includes a base surface facing the opening and that closes the opening,
wherein the overflow section is spaced apart from the base surface.

4. The cooler according to claim 2, wherein the second reservoir surrounds the first reservoir as viewed in the first direction.

5. The cooler according to claim 3, wherein the partition wall includes a first wall and a second wall that overlap with the opening as viewed in the first direction and that are spaced apart from each other in a second direction orthogonal to the first direction, and
either the first reservoir or the second reservoir is located between the first wall and the second wall.

6. The cooler according to claim 5, wherein each of the first wall and the second wall extends in a third direction orthogonal to the first direction and the second direction.

7. The cooler according to claim 6, wherein the first reservoir is located between the first wall and the second wall.

8. The cooler according to claim 7, wherein the first reservoir overlaps with a center of the opening as viewed in the first direction.

9. The cooler according to claim 2, wherein the inlet channel and the outlet channel are disposed at the bottom, and
each of the inlet channel and the outlet channel penetrates the bottom in the first direction.

10. The cooler according to claim 2, wherein the housing includes a body that includes the opening and that defines a portion of the internal space, and
the bottom is attached to the body.

11. The cooler according to claim 10, wherein the body and the partition wall are made of a material containing resin.

12. The cooler according to claim 11, wherein the partition wall is integral with the body.

13. The cooler according to claim 6, wherein the lid member includes a depressed section that is depressed in the first direction and that includes a portion defined by the base surface,
the lid member includes a heat-dissipating section protruding from the base surface, and
the heat-dissipating section is accommodated in the depressed section.

14. The cooler according to claim 13, wherein the heat-dissipating section includes a plurality of fins each extending in the second direction, and
the fins are arranged along the third direction.

15. A cooling structure for a semiconductor device, the cooling structure comprising:
the cooler according to claim 2, and
a semiconductor device attached to the cooler,
wherein the semiconductor device is attached to the housing, and
the semiconductor device closes the opening.

16. The cooling structure according to claim 15, wherein the semiconductor device includes a substrate, a conductive layer supported on the substrate, and a semiconductor element that is located opposite the substrate with respect to the conductive layer and bonded to the conductive layer, and
the substrate closes the opening.

17. A cooling structure for a semiconductor device, the cooling structure comprising:
the cooler according to claim 3, and
a semiconductor device attached to the cooler,
wherein the semiconductor device is attached to the lid member, and
the semiconductor device overlaps with the opening as viewed in the first direction.

18. A cooling structure for a semiconductor device, the cooling structure comprising:
a cooler including a plurality of internal spaces each recessed in a first direction, the plurality of internal spaces being arranged along a direction orthogonal to the first direction; and
a plurality of semiconductor devices attached to the cooler,
wherein the plurality of semiconductor devices individually overlap with the plurality of internal spaces as viewed in the first direction,
the cooler includes a plurality of inlet channels and a plurality of outlet channels that are configured as a system separate from the plurality of inlet channels,
the plurality of inlet channels are individually connected to the plurality of internal spaces, and
the plurality of outlet channels are individually connected to the plurality of internal spaces.
